(19) United States
(12) Patent Application Publication
(10) Pub. No.: US 2014/0273498 A1
(43) Pub. Date: Sep. 18, 2014

(54) SUBSTRATE PROCESSING APPARATUS AND SUBSTRATE PROCESSING METHOD

(71) Applicant: DAINIPPON SCREEN MFG. CO., LTD., KYOTO (JP)

(72) Inventors: Kenji KOBAYASHI, Kyoto (JP); Takemitsu MIURA, Kyoto (JP)

(73) Assignee: DAINIPPON SCREEN MFG. CO., LTD., KYOTO (JP)

(21) Appl. No.: 14/203,720

(22) Filed: Mar. 11, 2014

(30) Foreign Application Priority Data
Mar. 15, 2013 (JP) P2013-052878
Mar. 15, 2013 (JP) P2013-052879

(51) Int. Cl. H01L 21/306; H01L 21/67

(52) U.S. Cl. CPC H01L 21/306; H01L 21/6708
USPC 438/745; 156/345.21; 156/345.17

(57) ABSTRACT

In a substrate processing apparatus, provided are an upper nozzle for supplying a chemical liquid having a temperature higher than that of a substrate onto an upper surface of the substrate and a heating liquid supply nozzle for supplying a heating liquid having a temperature higher than that of the substrate onto a lower surface of the substrate. It is thereby possible to suppress or prevent a decrease in the temperature of the chemical liquid supplied on the upper surface of the substrate from a center portion of the substrate toward an outer peripheral portion thereof. In a supply nozzle, the heating liquid supply nozzle is positioned on the inner side of a heating gas supply nozzle for ejecting heating gas in drying the substrate. It is thereby possible to simplify and downsize a structure used for heating the lower surface of the substrate.

### TECHNICAL FIELD

The present invention relates to a technique for processing a substrate.

### BACKGROUND ART

In a process of manufacturing a semiconductor substrate (hereinafter, referred to simply as a “substrate”), conventionally, various processings are performed on a substrate by using a substrate processing apparatus. Japanese Patent Application Laid-Open No. 2004-158588 (Document 1), for example, discloses a substrate processing apparatus capable of removing organic substances deposited on a substrate by using a removal liquid. The substrate processing apparatus holds a rear surface of the substrate by adsorption with a vacuum chuck. Then, by supplying temperature-controlled deionized water onto the rear surface of the substrate from a rear-surface liquid nozzle before supplying the removal liquid onto a front surface of the substrate, the temperature of the substrate can be approximate to the temperature of the removal liquid. Alternatively, by supplying temperature-controlled nitrogen gas onto the rear surface of the substrate from a rear-surface gas nozzle, the temperature of the substrate can be approximate to the temperature of the removal liquid. It is therefore possible to improve the uniformity of the temperature of the removal liquid flowing on the front surface of the substrate and improve the inplane uniformity of the processing of removing the organic substances.

On the other hand, in a substrate processing apparatus disclosed in Japanese Patent Application Laid-Open No. 10-57877 (Document 2), provided is a double tube facing a center portion of a rear surface of a substrate. The double tube has an inner tube used for supplying nitrogen gas and an outer tube used for supplying deionized water. In the substrate processing apparatus, by supplying deionized water onto the rear surface to form a liquid film thereon when a developing solution is supplied onto a front surface of the substrate, it is possible to prevent deposition of the developing solution on the rear surface. Further, by supplying nitrogen gas onto the center portion of the rear surface when the substrate is dried while being rotated at high speed, the liquid at the center portion is moved to a position where the centrifugal force is applied.

In the substrate processing apparatus of Document 1, it is impossible to supply the deionized water or the nitrogen gas onto a portion of the lower surface of the substrate, which is adsorbed by the vacuum chuck. For this reason, there is a limitation in improving the inplane uniformity of the temperature of the substrate. Further, in the case where a processing is performed by supplying a chemical liquid onto the lower surface of the substrate, when the temperature-controlled nitrogen gas is supplied onto the lower surface, there is a possibility that the chemical liquid supplied onto the lower surface may be scattered by the nitrogen gas.

### SUMMARY OF INVENTION

The present invention is intended for a substrate processing apparatus for processing a substrate, and it is an object of the present invention to perform a liquid processing on a lower surface of a substrate while suppressing a decrease in the temperature at an outer peripheral portion of the substrate. It is another object of the present invention to heat the substrate when the substrate is dried.

The substrate processing apparatus according to one aspect of the present invention includes a substrate supporting part for supporting an outer edge portion of a substrate in a horizontal state, a substrate rotating mechanism for rotating the substrate supporting part together with the substrate around a central axis directed in a vertical direction, a processing liquid supply nozzle for supplying a processing liquid having a temperature higher than that of the substrate onto an upper surface of the substrate, and at least one supply nozzle directed to a lower surface of the substrate between the central axis and an outer peripheral edge of the substrate. In the substrate processing apparatus, each supply nozzle of the at least one supply nozzle includes a heating liquid supply nozzle for supplying a heating liquid having a temperature higher than that of the substrate onto the lower surface of the substrate and a heating gas supply nozzle for ejecting heating gas having a temperature higher than that of the substrate toward the lower surface of the substrate, the heating gas supply nozzle sharing a partition wall which comes into direct contact with the heating liquid and the heating gas, with the heating liquid supply nozzle. It is thereby possible to perform a liquid processing on the lower surface of the substrate while suppressing a decrease in the temperature at an outer peripheral portion of the substrate. Further, it is possible to heat the substrate when the substrate is dried.

In one preferred embodiment of the present invention, the each supply nozzle is a double tube in which the heating gas supply nozzle surrounds the periphery of the heating liquid supply nozzle.

In another preferred embodiment of the present invention, the at least one supply nozzle includes a plurality of supply nozzles, and two or more supply nozzles among the plurality of supply nozzles are positioned on the same circumference around the central axis.

In still another preferred embodiment of the present invention, the at least one supply nozzle includes a plurality of supply nozzles, and a distance between one supply nozzle among the plurality of supply nozzles and the central axis in a radial direction is different from that between another supply nozzle and the central axis in the radial direction.

In yet another preferred embodiment of the present invention, the processing liquid and the heating liquid are the same liquid, and the substrate processing apparatus further includes a liquid heating part for heating the liquid to be supplied to the processing liquid supply nozzle and the heating liquid supply nozzle of the each supply nozzle.

Preferably, the heating liquid in the heating liquid supply nozzle is heated by the heating gas in the heating gas supply nozzle through the partition wall in the each supply nozzle, to have a temperature higher than that of the processing liquid.

In another preferred embodiment of the present invention, the heating liquid in the heating liquid supply nozzle is heated by the heating gas in the heating gas supply nozzle through the partition wall in the each supply nozzle.

In still another preferred embodiment of the present invention, the substrate supporting part has an annular shape around the central axis, and the substrate processing apparatus further includes a lower surface facing part having a facing surface which faces the lower surface of the substrate inside the substrate supporting part, and in the substrate processing apparatus, the facing surface is a sloped surface which gets farther away from the substrate as a distance from the central axis becomes larger.

In yet another preferred embodiment of the present invention, the at least one supply nozzle is inclined with respect to the central axis.

In still another preferred embodiment of the present invention, the processing liquid supply nozzle is so fixed as to face a center portion of the upper surface of the substrate.

In yet another preferred embodiment of the present invention, the substrate processing apparatus further includes a sealed space forming part forming an internal space which is sealed, in which a processing is performed on the substrate with the processing liquid.

The substrate processing apparatus according to another aspect of the present invention includes a substrate supporting part for supporting an outer edge portion of a substrate in a horizontal state, a substrate rotating mechanism for rotating the substrate supporting part together with the substrate around a central axis directed in a vertical direction, a processing liquid supply nozzle for supplying a processing liquid having a temperature higher than that of the substrate onto an upper surface of the substrate, at least one heating liquid supply nozzle for supplying a heating liquid having a temperature higher than that of the substrate onto a lower surface of the substrate between the central axis and an outer peripheral edge of the substrate, and at least one heating gas supply nozzle for ejecting heating gas having a temperature higher than that of the substrate toward the lower surface of the substrate between the central axis and the outer peripheral edge of the substrate. It is thereby possible to perform a liquid processing on the lower surface of the substrate while suppressing a decrease in the temperature at an outer peripheral portion of the substrate. Further, it is possible to heat the substrate when the substrate is dried.

In one preferred embodiment of the present invention, the substrate processing apparatus further includes a control part for controlling the substrate rotating mechanism, supply of the processing liquid from the processing liquid supply nozzle, supply of the heating liquid from the at least one heating liquid supply nozzle, and supply of the heating gas from the at least one heating gas supply nozzle, and in the substrate processing apparatus, the processing liquid is supplied onto the upper surface of the substrate, and concurrently with the supply of the processing liquid, the heating liquid is supplied onto the lower surface of the substrate, with the substrate being rotated, and after stopping supply of the processing liquid and the heating liquid, the heating gas is ejected toward the lower surface of the substrate, with the substrate being rotated, to thereby dry the substrate, under the control by the control part.

In another preferred embodiment of the present invention, the substrate processing apparatus further includes a control part for controlling the substrate rotating mechanism, supply of the processing liquid from the processing liquid supply nozzle, supply of the heating liquid from the at least one heating liquid supply nozzle, and supply of the heating gas from the at least one heating gas supply nozzle, and in the substrate processing apparatus, the processing liquid is supplied onto the upper surface of the substrate, with the substrate being rotated, and concurrently with the supply of the processing liquid, the heating liquid is supplied onto the lower surface of the substrate and the heating gas is supplied into a space below the substrate, under the control by the control part.

The present invention is also intended for a substrate processing method of processing a substrate. The substrate processing method according to one aspect of the present invention includes a) supplying a processing liquid having a temperature higher than that of a substrate onto an upper surface of the substrate while rotating the substrate in a horizontal state around a central axis directed in a vertical direction, b) supplying a heating liquid having a temperature higher than that of the substrate onto a lower surface of the substrate between the central axis and an outer peripheral edge of the substrate from at least one heating liquid supply nozzle concurrently with the operation a), and c) ejecting heating gas having a temperature higher than that of the substrate toward the lower surface of the substrate between the central axis and the outer peripheral edge of the substrate from at least one heating gas supply nozzle while rotating the substrate after stopping supply of the processing liquid and the heating liquid, to thereby dry the substrate.

The substrate processing method according to another aspect of the present invention includes a) supplying a processing liquid having a temperature higher than that of a substrate onto an upper surface of the substrate while rotating the substrate in a horizontal state around a central axis directed in a vertical direction, b) supplying a heating liquid having a temperature higher than that of the substrate onto a lower surface of the substrate between the central axis and an outer peripheral edge of the substrate from at least one heating liquid supply nozzle concurrently with the operation a), and c) supplying heating gas having a temperature higher than that of the substrate into a space below the substrate from at least one heating gas supply nozzle concurrently with the operation b).

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a cross-sectional view showing a substrate processing apparatus in accordance with a first preferred embodiment;

FIG. 2 is a cross section of a supply nozzle;

FIG. 3 is a longitudinal section of the supply nozzle;

FIG. 4 is a block diagram showing a gas-liquid supply part and a gas-liquid exhaust part;

FIG. 5 is a plan view of a lower surface facing part;

FIG. 6 is a cross-sectional view of the lower surface facing part;

FIG. 7 is a flowchart showing an operation flow of the substrate processing apparatus;

FIGS. 8 and 9 are cross-sectional views each showing the substrate processing apparatus;

FIGS. 10 and 11 are graphs each showing a temperature distribution of a substrate in performing a chemical liquid processing;

FIG. 12 is a flowchart showing part of an operation flow of the substrate processing apparatus;

FIG. 13 is a graph showing a temperature distribution of a substrate in performing the chemical liquid processing;

FIGS. 14 and 15 are plan views each showing another exemplary arrangement of the supply nozzles;

FIG. 16 is a cross-sectional view showing a substrate processing apparatus in accordance with a second preferred embodiment;

FIG. 17 is a block diagram showing the gas-liquid supply part and the gas-liquid exhaust part;

FIG. 18 is a plan view of a lower surface facing part;

FIG. 19 is a cross-sectional view of the lower surface facing part;

FIGS. 20 and 21 are cross-sectional views each showing the substrate processing apparatus;

FIGS. 22 and 23 are graphs each showing a temperature distribution of a substrate in performing a chemical liquid processing; and

FIG. 24 is a cross section showing another example of the supply nozzle.

### DESCRIPTION OF EMBODIMENTS

FIG. 1 is a cross-sectional view showing a substrate processing apparatus 1 in accordance with the first preferred embodiment of the present invention. The substrate processing apparatus 1 is a single-substrate processing apparatus for supplying a processing liquid to a semiconductor substrate 9 (hereinafter, referred to simply as a “substrate 9”) having a substantially disk-like shape, to thereby process substrates 9 one by one. In FIG. 1, hatching of the cross sections of some constituent elements in the substrate processing apparatus 1 is omitted (the same applies to other cross-sectional views).

The substrate processing apparatus 1 includes a chamber 12, a top plate 123, a chamber opening and closing mechanism 131, a substrate holding part 14, a substrate rotating mechanism 15, a liquid receiving part 16, and a cover 17. The cover 17 covers the upper portion and the side of the chamber 12.

The chamber 12 includes a chamber body 121 and a chamber cover 122. The chamber 12 has a substantially cylindrical shape around the central axis J1 directed in a vertical direction. The chamber body 121 includes a chamber bottom 210 and a chamber sidewall 214. The chamber bottom 210 includes a center portion 211 having a substantially disk-like shape, an inner sidewall 212 having a cylindrical shape extending downward from an outer edge portion of the center portion 211, an annular bottom 213 having a substantially annular disk-like shape extending outward in a radial direction from a lower end of the inner sidewall 212, an outer sidewall 215 having a substantially cylindrical shape extending upward from an outer edge portion of the annular bottom 213, and a base part 216 having a substantially annular disk-like shape extending outward in the radial direction from an upper end portion of the outer sidewall 215.

The chamber sidewall 214 has an annular shape around the central axis J1. The chamber sidewall 214 protrudes upward from an inner edge portion of the base part 216. A material forming the chamber sidewall 214 also serves as part of the liquid receiving part 16, as described later. In the following description, a space surrounded by the chamber sidewall 214, the outer sidewall 215, the annular bottom 213, the inner sidewall 212, and an outer edge portion of the center portion 211 is referred to as a lower annular space 217.

When the substrate 9 is supported by a substrate supporting part 141 (described later) of the substrate holding part 14, a lower surface 92 of the substrate 9 faces an upper surface 211a of the center portion 211 of the chamber bottom 210. In the following description, the center portion 211 of the chamber bottom 210 is referred to as a “lower surface facing part 211”, and the upper surface 211a of the center portion 211 is referred to as a “facing surface 211a”. The detail of the lower surface facing part 211 will be described.

The chamber cover 122 has a substantially disk-like shape perpendicular to the central axis J1, including the upper portion of the chamber 12. The chamber cover 122 closes an upper opening of the chamber body 121. FIG. 1 shows a state where the chamber cover 122 is separated from the chamber body 121. When the chamber cover 122 closes the upper opening of the chamber body 121, an outer edge portion of the chamber cover 122 comes into contact with an upper portion of the chamber sidewall 214.

The chamber opening and closing mechanism 131 moves the chamber cover 122 which is a movable part of the chamber 12, relatively to the chamber body 121 which is the other portion of the chamber 12 in the vertical direction. The chamber opening and closing mechanism 131 serves as a cover up-and-down moving mechanism for moving the chamber cover 122 up and down. When the chamber opening and closing mechanism 131 moves the chamber cover 122 in the vertical direction, the top plate 123 is also moved, together with the chamber cover 122, in the vertical direction. When the chamber cover 122 comes into contact with the chamber body 121 to close the upper opening thereof and the chamber cover 122 is pressed toward the chamber body 121, a chamber space 120 (see FIG. 7) which is sealed is formed inside the chamber 12. In other words, the chamber space 120 is sealed by closing the upper opening of the chamber body 121 by the chamber cover 122.

The substrate holding part 14 is disposed in the chamber 12 and holds the substrate 9 in a horizontal state. In other words, the substrate 9 is held by the substrate holding part 14, in a state where one main surface 91 (hereinafter, referred to as an “upper surface 91”) thereof on which a fine pattern is formed is directed upward, being perpendicular to the central axis J1. The substrate holding part 14 includes the above-described substrate supporting part 141 for supporting an outer edge portion (i.e., a portion including an outer peripheral edge and the vicinity thereof) of the substrate 9 from below and a substrate retaining part 142 for retaining the outer edge portion of the substrate 9 from above, which is supported by the substrate supporting part 141. The substrate supporting part 141 has a substantially annular shape around the central axis J1. The substrate supporting part 141 includes a supporting part base 413 having a substantially annular disk-like shape around the central axis J1 and a plurality of first contact parts 411 fixed to an upper surface of the supporting part base 413. The substrate retaining part 142 includes a plurality of second contact parts 421 fixed to a lower surface of the top plate 123. Positions of the plurality of second contact parts 421 in a circumferential direction are actually different from those of the plurality of first contact parts 411 in the circumferential direction.

The top plate 123 has a substantially disk-like shape perpendicular to the central axis J1. The top plate 123 is disposed below the chamber cover 122 and above the substrate supporting part 141. The top plate 123 has an opening at its center portion. When the substrate 9 is supported by the substrate supporting part 141, the upper surface 91 of the substrate 9 faces the lower surface of the top plate 123 which is perpendicular to the central axis J1. A diameter of the top plate 123 is larger than that of the substrate 9, and an outer peripheral edge of the top plate 123 is positioned outer than the outer peripheral edge of the substrate 9 in the radial direction all around the circumference.

In the state of FIG. 1, the top plate 123 is supported by the chamber cover 122, being suspended therefrom. The chamber cover 122 has a plate holding part 222 having an annular shape, at its center portion. The plate holding part 222 includes a cylindrical portion 223 having a substantially cylindrical shape around the central axis J1 and a flange portion 224 having a substantially disk-like shape around the central axis J1. The flange portion 224 extends inward in the radial direction from a lower end of the cylindrical portion 223.

The top plate 123 includes a held part 237 having an annular shape. The held part 237 includes a cylindrical portion 238 having a substantially cylindrical shape around the central axis J1 and a flange portion 239 having a substantially disk-like shape around the central axis J1. The cylindrical portion 238 extends upward from an upper surface of the top plate 123. The flange portion 239 extends outward in the radial direction from an upper end of the cylindrical portion 238. The cylindrical portion 238 is positioned inner than the cylindrical portion 223 of the plate holding part 222 in the radial direction. The flange portion 239 is positioned above the flange portion 224 of the plate holding part 222 and faces the flange portion 224 in the vertical direction. When a lower surface of the flange portion 239 of the held part 237 comes into contact with an upper surface of the flange portion 224 of the plate holding part 222, the top plate 123 is attached to the chamber cover 122, being suspended from the chamber cover 122.

On a lower surface of an outer edge portion of the top plate 123, a plurality of first engagement parts 241 are arranged in the circumferential direction, and on an upper surface of the supporting part base 413, a plurality of second engagement parts 242 are arranged in the circumferential direction. The first engagement parts 241 and the second engagement parts 242 are actually arranged at different positions from the positions of the plurality of first contact parts 411 of the substrate supporting part 141 and the plurality of second contact parts 421 of the substrate retaining part 142 in the circumferential direction. It is preferable that these engagement parts should be provided in three or more pairs, and in the present preferred embodiment, four pairs are provided. At a lower portion of the first engagement part 241, provided is a recessed portion which is recessed upward. The second engagement part 242 protrudes upward from the supporting part base 413.

The substrate rotating mechanism 15 is a so-called hollow motor. The substrate rotating mechanism 15 includes a stator part 151 having an annular shape around the central axis J1 and a rotor part 152 having an annular shape. The rotor part 152 includes a permanent magnet having a substantially annular shape. A surface of the permanent magnet is molded of a PTFE (polytetrafluoroethylene) resin. The rotor part 152 is disposed inside the lower annular space 217 in the chamber 12. Above the rotor part 152, attached is the supporting part base 413 of the substrate supporting part 141 with a connecting member interposed therebetween. The supporting part base 413 is disposed above the rotor part 152.

The stator part 151 is disposed in the periphery of the rotor part 152 outside the chamber 12, i.e., disposed on the outer side of the rotor part 152 in the radial direction. In the present preferred embodiment, the stator part 151 is fixed to the outer sidewall 215 and the base part 216 of the chamber bottom 210 and positioned below the liquid receiving part 16. The stator part 151 includes a plurality of coils arranged in the circumferential direction around the central axis J1.

By supplying current to the stator part 151, a rotating force is generated around the central axis J1 between the stator part 151 and the rotor part 152. The rotor part 152 is thereby rotated in a horizontal state around the central axis J1. With a magnetic force exerted between the stator part 151 and the rotor part 152, the rotor part 152 floats in the chamber 12, not being in direct or indirect contact with the chamber 12, and rotates the substrate 9 together with the substrate supporting part 141 around the central axis J1, being in a floating state.

The liquid receiving part 16 includes a cup part 161, a cup moving mechanism 162, and a cup facing part 163. The cup part 161 has an annular shape around the central axis J1 and is positioned outer than the chamber 12 in the radial direction all around the circumference. The cup moving mechanism 162 moves the cup part 161 in the vertical direction. The cup moving mechanism 162 is positioned outer than the cup part 161 in the radial direction. The cup moving mechanism 162 is disposed at the different position from the position of the above-described chamber opening and closing mechanism 131 in the circumferential direction. The cup facing part 163 is positioned below the cup part 161 and faces the cup part 161 in the vertical direction. The cup facing part 163 is part of a material which forms the chamber sidewall 214. The cup facing part 163 has an annular liquid receiving recessed portion 165 positioned outer than the chamber sidewall 214 in the radial direction.

The cup part 161 includes a sidewall 611, an upper surface part 612, and a bellows 617. The sidewall 611 has a substantially cylindrical shape around the central axis J1. The upper surface part 612 has a substantially annular disk-like shape around the central axis J1, extending from an upper end portion of the sidewall 611 inward and outward in the radial direction. A lower portion of the sidewall 611 is positioned inside the liquid receiving recessed portion 165 of the cup facing part 163.

The bellows 617 has a substantially cylindrical shape around the central axis J1 and is extensible in the vertical direction. The bellows 617 is provided outer than the sidewall 611 in the radial direction, all around the circumference of the sidewall 611. The bellows 617 is formed of a material which does not allow the passage of gas and liquid. An upper end portion of the bellows 617 is connected to a lower surface of an outer edge portion of the upper surface part 612 all around the circumference. In other words, the upper end portion of the bellows 617 is indirectly connected to the sidewall 611 with the upper surface part 612 interposed therebetween. A connecting portion between the bellows 617 and the upper surface part 612 is sealed, and this prevents the passage of gas and liquid. A lower end portion of the bellows 617 is indirectly connected to the chamber body 121 with the cup facing part 163 interposed therebetween. Also at a connecting portion between the lower end portion of the bellows 617 and the cup facing part 163, the passage of gas and liquid is prevented.

An upper nozzle 181 is fixed to a center portion of the chamber cover 122. The upper nozzle 181 is so fixed to the chamber cover 122 as to face the center portion of the upper surface 91 of the substrate 9. The upper nozzle 181 is insertable into the opening of the center portion of the top plate 123. The upper nozzle 181 has a liquid discharge port at its center portion and serves as a processing liquid supply nozzle for supplying a processing liquid onto the upper surface 91 of the substrate 9. The upper nozzle 181 also has an ejection port for ejecting gas, which is provided around the liquid discharge port. At a center portion of the lower surface facing part 211 of the chamber bottom 210, a lower nozzle 182 is attached. The lower nozzle 182 has a liquid discharge port at its center portion and faces the center portion of the lower surface 92 of the substrate 9. At the lower surface facing part 211, a plurality of supply nozzles 180 directed to the lower surface 92 of the substrate 9 are further provided.

FIG. 2 is a cross section of the supply nozzle 180, which is perpendicular to a central axis J2. FIG. 3 is a longitudinal section of the supply nozzle 180, which includes the central axis J2. Other supply nozzles 180 have the same structure as that of the supply nozzle 180 shown in FIGS. 2 and 3. As shown in FIGS. 2 and 3, the supply nozzle 180 includes a heating gas supply nozzle 180a and a heating liquid supply nozzle 180b. Each supply nozzle 180 is a double tube in which the heating gas supply nozzle 180a surrounds the periphery of the heating liquid supply nozzle 180b all around the circumference.

Each supply nozzle 180 includes an inner peripheral wall 801 having a substantially cylindrical shape and an outer peripheral wall 802 having a substantially cylindrical shape which surrounds the periphery of the inner peripheral wall 801 all around the circumference. As shown in FIG. 2, the respective cross sections of the inner peripheral wall 801 and the outer peripheral wall 802 are substantially concentric. A discharge port 1805 of the heating liquid supply nozzle 180b which is a front end of the inner peripheral wall 801 and a portion of the inner peripheral wall 801 in the vicinity of the discharge port 1805 protrude than an ejection port 1802 of the heating gas supply nozzle 180a which is a front end of the outer peripheral wall 802. Preferably, the inner peripheral wall 801 is formed of a material having relative high thermal conductivity and so thinned as to have higher thermal conductivity. The outer peripheral wall 802 is formed of a material having relative low thermal conductivity and so thickened as to have lower thermal conductivity. Arrangement of the supply nozzles 180 and the like will be described later.

FIG. 4 is a block diagram showing a gas-liquid supply part 18 and a gas-liquid exhaust part 19 included in the substrate processing apparatus 1. The gas-liquid supply part 18 includes a chemical liquid supply part 183, a deionized water supply part 184, an IPA supply part 185, an inert gas supply part 186, a heating gas supply part 187, and a liquid heating part 188, besides the supply nozzles 180, the upper nozzle 181, and the lower nozzle 182 described above.

The chemical liquid supply part 183 is connected to the liquid heating part 188, and the liquid heating part 188 is connected to the upper nozzle 181 with a valve interposed therebetween and also to the respective heating liquid supply nozzles 180b of the plurality of supply nozzles 180 with a valve interposed therebetween. A chemical liquid supplied from the chemical liquid supply part 183 to the liquid heating part 188 is heated in the liquid heating part 188. The heated chemical liquid is supplied to the upper nozzle 181 and the plurality of heating liquid supply nozzles 180b. The start and stop of the supply of the heated chemical liquid to the upper nozzle 181 and the start and stop of the supply of the heated chemical liquid (hereinafter, referred to also as a “heating liquid”) to the heating liquid supply nozzles 180b can be individually controlled by a control part 10.

The deionized water supply part 184 and the IPA supply part 185 are connected to the upper nozzle 181 each with a valve interposed therebetween. The lower nozzle 182 is connected to the deionized water supply part 184 with a valve interposed therebetween. The upper nozzle 181 is also connected to the inert gas supply part 186 with a valve interposed therebetween. The upper nozzle 181 is part of a gas supply part for supplying gas into the chamber 12. The plurality of heating gas supply nozzles 180a are connected to the heating gas supply part 187 with a valve interposed therebetween.

A first exhaust path 191 connected to the liquid receiving recessed portion 165 of the liquid receiving part 16 is connected to a gas-liquid separating part 193. The gas-liquid separating part 193 is connected to an outer gas exhaust part 194, a chemical liquid collecting part 195, and a liquid exhaust part 196 each with a valve interposed therebetween. A second exhaust path 192 connected to the chamber bottom 210 of the chamber 12 is connected to a gas-liquid separating part 197. The gas-liquid separating part 197 is connected to an inner gas exhaust part 198 and a liquid exhaust part 199 each with a valve interposed therebetween. The constituent elements in the gas-liquid supply part 18 and the gas-liquid exhaust part 19 are controlled by the control part 10. The chamber opening and closing mechanism 131, the substrate rotating mechanism 15, and the cup moving mechanism 162 (see FIG. 1) are also controlled by the control part 10.

A chemical liquid supplied from the chemical liquid supply part 183 onto the substrate 9 through the upper nozzle 181 and the plurality of heating liquid supply nozzles 180b is a processing liquid to be used for processing the substrate by utilizing chemical reaction, which is, for example, an etching solution such as hydrofluoric acid, a tetramethylammonium hydroxide solution, or the like. The deionized water supply part 184 supplies deionized water (DIW) onto the substrate 9 through the upper nozzle 181 or the lower nozzle 182. The IPA supply part 185 supplies isopropyl alcohol (IPA) onto the substrate 9 through the upper nozzle 181. In the substrate processing apparatus 1, a processing liquid supply part for supplying any processing liquid other than the above processing liquids (the above-described chemical liquid, deionized water, and IPA) may be provided.

The inert gas supply part 186 supplies an inert gas into the chamber 12 through the upper nozzle 181. The heating gas supply part 187 supplies heated gas (e.g., a high-temperature inert gas) onto the lower surface 92 of the substrate 9 through the plurality of heating gas supply nozzles 180a. In the present preferred embodiment, the gas used in the inert gas supply part 186 and the heating gas supply part 187 is nitrogen gas (N₂), but any gas other than nitrogen gas may be used. Further, in the case where the heated inert gas is used in the heating gas supply part 187, the explosion-proof countermeasure in the substrate processing apparatus 1 can be simplified or is not needed.

In each supply nozzle 180 shown in FIGS. 2 and 3, the heated liquid (hereinafter, referred to as the “heating liquid”) supplied from the chemical liquid supply part 183 and the liquid heating part 188 to the heating liquid supply nozzles 180b comes into direct contact with the inner peripheral wall 801. Further, the heated gas (hereinafter, referred to as a “heating gas”) supplied from the heating gas supply part 187 to the heating gas supply nozzles 180a comes into direct contact with the inner peripheral wall 801 and the outer peripheral wall 802. The inner peripheral wall 801 of each supply nozzle 180 is a partition wall which comes into direct contact with the heating liquid and the heating gas and prevents mixture of the heating liquid and the heating gas in the supply nozzle 180, and is shared by the heating gas supply nozzle 180a and the heating liquid supply nozzle 180b.

FIG. 5 is a plan view showing an arrangement of the plurality of supply nozzles 180 on the lower surface facing part 211 of the chamber bottom 210. In FIG. 5, the whole of each supply nozzle 180 is not shown, and an attachment position of each supply nozzle 180 on the lower surface facing part 211 is represented by a solid-line circle with reference number “1801” (the same applies to FIGS. 14 and 15). As shown in FIG. 5, six supply nozzles 180 are provided on the lower surface facing part 211. The six supply nozzles 180 are disposed at regular angular intervals (at intervals of 60 degrees) on the same circumference around the central axis J1. For example, in the substrate processing apparatus 1 used for processing a substrate 9 having a radius of about 150 mm, a distance in the radial direction between the center of the discharge port 1805 of each supply nozzle 180 and the central axis J1 is about 90 mm.

FIG. 6 is an enlarged cross-sectional view showing the vicinity of the lower surface facing part 211. As shown in FIG. 6, when the substrate 9 is supported by the substrate supporting part 141, the facing surface 211a of the lower surface facing part 211 faces the lower surface 92 of the substrate 9 on the inner side of the substrate supporting part 141 in the radial direction. The facing surface 211a is a sloped surface which goes downward (in other words, gets farther away from the substrate 9) as a distance from the central axis J1 becomes larger, extending almost entirely over the lower surface 92 of the substrate 9. A distance between the facing surface 211a and the lower surface 92 of the substrate 9 becomes minimum in the vicinity of the lower nozzle 182, and is e.g., 5 mm. Further, the distance becomes maximum at the outer edge portion of the substrate 9, and is e.g., 30 mm.

Each supply nozzle 180 protrudes from the facing surface 211a. The heating liquid supply nozzle 180b of each supply nozzle 180 is connected to the liquid heating part 188 (see FIG. 4) through a heating liquid pipe 806 and a heating liquid manifold 807 formed inside the lower surface facing part 211. The heating liquid manifold 807 has a substantially annular shape around the central axis J1. Through a plurality of heating liquid pipes 806, the plurality of heating liquid supply nozzles 180b are connected to the heating liquid manifold 807, respectively.

The heating gas supply nozzle 180a of each supply nozzle 180 is connected to the heating gas supply part 187 through a heating gas pipe 808 and a heating gas manifold 809 formed inside the lower surface facing part 211. The heating gas manifold 809 has a substantially annular shape around the central axis J1, covering an outer surface of the heating liquid manifold 807. Through a plurality of heating gas pipes 808, the plurality of heating gas supply nozzles 180a are connected to the heating gas manifold 809, respectively. Each heating gas pipe 808 surrounds the periphery of the heating liquid pipe 806 all around the circumference. Assuming that the heating liquid pipe 806 and the heating gas pipe 808 which are connected to one supply nozzle 180 are collectively referred to as a supply pipe 804 and the heating liquid manifold 807 and the heating gas manifold 809 are collectively referred to as a manifold 805, a plurality of supply pipes 804 are double tubes which connect the manifold 805 and the plurality of supply nozzles 180, respectively.

The ejection port 1802 of each heating gas supply nozzle 180a and the discharge port 1805 of each heating liquid supply nozzle 180b are close to the lower surface 92 of the substrate 9 above the facing surface 211a. Each supply nozzle 180 is fixed to the lower surface facing part 211 so that its central axis J2 may extend almost along the normal of the facing surface 211a at the attachment position 1801. In other words, each supply nozzle 180 is inclined with respect to the central axis J1. Therefore, each heating gas supply nozzle 180a is inclined with respect to the central axis J1 so that the ejection port 1802 may be positioned slightly outer than the attachment position 1801 in the radial direction. Further, each heating liquid supply nozzle 180b is also inclined with respect to the central axis J1 so that the discharge port 1805 may be positioned slightly outer than the attachment position 1801 in the radial direction.

FIG. 7 is a flowchart showing an operation flow for processing the substrate 9 in the substrate processing apparatus 1. In the substrate processing apparatus 1, in a state where the chamber cover 122 is separated from the chamber body 121 and positioned thereabove and the cup part 161 is separated from the chamber cover 122 and positioned therebelow as shown in FIG. 1, the substrate 9 is loaded into the chamber 12 by an external transfer mechanism and supported by the substrate supporting part 141 from below (Step S11). Hereinafter, the state of the chamber 12 and the cup part 161 shown in FIG. 1 is referred to as an “open state”. An opening between the chamber cover 122 and the chamber sidewall 214 has an annular shape around the central axis J1 and is hereinafter referred to as an “annular opening 81”. In the substrate processing apparatus 1, when the chamber cover 122 is separated from the chamber body 121, the annular opening 81 is formed around the substrate 9 (in other words, outer than the substrate 9 in the radial direction). In Step S11, the substrate 9 is loaded through the annular opening 81.

After the substrate 9 is loaded, the cup part 161 moves upward from the position shown in FIG. 1 up to the position shown in FIG. 8, to be positioned outer than the annular opening 81 in the radial direction all around the circumference. In the following description, the state of the chamber 12 and the cup part 161 shown in FIG. 8 is referred to as a “first sealed state”. Further, the position of the cup part 161 shown in FIG. 8 is referred to as a “liquid receiving position” and the position of the cup part 161 shown in FIG. 1 is referred to as an “escape position”. The cup moving mechanism 162 moves the cup part 161 in the vertical direction between the liquid receiving position which is outer than the annular opening 81 in the radial direction and the escape position below the liquid receiving position.

In the cup part 161 positioned at the liquid receiving position, the sidewall 611 faces the annular opening 81 in the radial direction. Further, an upper surface of an inner edge portion of the upper surface part 612 is in contact with a lip seal 232 positioned at a lower end of an outer edge portion of the chamber cover 122 all around the circumference. Between the chamber cover 122 and the upper surface part 612 of the cup part 161, formed is a seal part for preventing the passage of gas and liquid. This forms a sealed internal space (hereinafter, referred to as an “enlarged sealed space 100”) surrounded by the chamber body 121, the chamber cover 122, the cup part 161, and the cup facing part 163.

The enlarged sealed space 100 is a space which is formed when the chamber space 120 between the chamber cover 122 and the chamber body 121 and a side space 160 surrounded by the cup part 161 and the cup facing part 163 communicate with each other through the annular opening 81. The chamber cover 122, the chamber body 121, the cup part 161, and the cup facing part 163 serves as a sealed space forming part which forms the enlarged sealed space 100.

In the first sealed state, the plurality of second contact parts 421 of the substrate retaining part 142 are in contact with the outer edge portion of the substrate 9. On the lower surface of the top plate 123 and on the supporting part base 413 of the substrate supporting part 141, provided are a plurality of pairs of magnets (not shown) in each of which two magnets face each other in the vertical direction. Hereinafter, each pair of magnets is referred to also as “a magnet pair”. In the substrate processing apparatus 1, a plurality of magnet pairs are disposed at regular angular intervals at positions different from those of the first contact parts 411, the second contact parts 421, the first engagement parts 241, and the second engagement parts 242 in the circumferential direction. In a state where the substrate retaining part 142 is in contact with the substrate 9, with a magnetic force (attractive force) exerted between each magnet pair, a downward force is exerted on the top plate 123. The substrate retaining part 142 thereby presses the substrate 9 toward the substrate supporting part 141.

In the substrate processing apparatus 1, the substrate retaining part 142 presses the substrate 9 toward the substrate supporting part 141 with the weight of the top plate 123 and the magnetic forces of the magnet pairs, and it is thereby possible to strongly hold the substrate 9 being sandwiched from above and below by the substrate retaining part 142 and the substrate supporting part 141.

In the first sealed state, the flange portion 239 of the held part 237 is separated above from the flange portion 224 of the plate holding part 222, and the plate holding part 222 is out of contact with the held part 237. In other words, the plate holding part 222 releases holding of the top plate 123. Therefore, the top plate 123, being independent of the chamber cover 122, is rotated by the substrate rotating mechanism 15, together with the substrate holding part 14 and the substrate 9 held by the substrate holding part 14.

Further, in the first sealed state, the second engagement part 242 engages with a lower recessed portion of the first engagement part 241. The top plate 123 thereby engages with the supporting part base 413 of the substrate supporting part 141 in the circumferential direction around the central axis J1. In other words, the first engagement part 241 and the second engagement part 242 serve as a position regulating member for regulating a relative position of the top plate 123 with respect to the substrate supporting part 141 in a rotation direction (in other words, for fixing a relative position in the circumferential direction). When the chamber cover 122 moves down, the substrate rotating mechanism 15 controls a rotation position of the supporting part base 413 so that the first engagement part 241 may engage with the second engagement part 242.

Subsequently, rotation of the substrate 9 is started by the substrate rotating mechanism 15 at a constant number of rotation (relatively low number of rotation, and hereinafter, referred to as “the steady number of rotation”). Further, the supply of the inert gas (herein, nitrogen gas) from the inert gas supply part 186 (see FIG. 4) into the enlarged sealed space 100 is started, and the exhaust of gas from the enlarged sealed space 100 by the outer gas exhaust part 194 is also started. After a predetermined time elapses, the enlarged sealed space 100 is thereby brought into an inert gas filled state where the inert gas is filled therein (in other words, into a low oxygen atmosphere where the oxygen concentration is low). Further, the supply of the inert gas into the enlarged sealed space 100 and the exhaust of the gas from the enlarged sealed space 100 may be performed in the open state shown in FIG. 1.

Next, under the control by the control part 10, the supply of the heating liquid which is the chemical liquid heated to a temperature higher than that of the substrate 9 is started toward the lower surface 92 of the substrate 9 from the respective heating liquid supply nozzles 180b of the plurality of supply nozzles 180. The heating liquid from each heating liquid supply nozzle 180b is continuously supplied onto the lower surface 92 of the substrate 9 between the central axis J1 and an outer peripheral edge of the substrate 9. With the rotation of the substrate 9, the heating liquid supplied onto the lower surface 92 spreads toward the outer peripheral portion of the substrate 9. A chemical liquid processing on the lower surface 92 of the substrate 9 is thereby started and heating of the substrate 9 is also started. The temperature of the heating liquid is determined as appropriate in accordance with the type of chemical liquid, the type of processing on the substrate 9, or the like, and is, e.g., about 50 to 80° C. Further, the total flow rate of the heating liquid to be supplied from the plurality of heating liquid supply nozzles 180b onto the lower surface 92 of the substrate 9 is, e.g., about 2 to 3 liters per minute.

After the substrate 9 is heated to a predetermined temperature, under the control by the control part 10, the supply of the chemical liquid heated to a temperature higher than that of the substrate 9 is started from the upper nozzle 181 toward the center portion of the upper surface 91 of the substrate 9 being rotated. The discharge of the chemical liquid toward the upper surface 91 of the substrate 9 is performed only on the center portion of the substrate 9, not on any portion other than the center portion. The chemical liquid from the upper nozzle 181 is continuously supplied onto the upper surface 91 of the substrate 9 being rotated. With the rotation of the substrate 9, the chemical liquid on the upper surface 91 spreads toward the outer peripheral portion of the substrate 9, and the entire upper surface 91 is covered with the chemical liquid.

The supply of the heating liquid from the heating liquid supply nozzles 180b continues also while the chemical liquid is supplied from the upper nozzle 181. In the enlarged sealed space 100, while the substrate 9 is heated to approximately a predetermined temperature, etching is thereby performed on the upper surface 91 of the substrate 9 by using the chemical liquid supplied from the upper nozzle 181 and etching is also performed on the lower surface 92 of the substrate 9 by using the heating liquid supplied from the heating liquid supply nozzles 180b (Step S12). The flow rate of the chemical liquid to be supplied from the upper nozzle 181 onto the upper surface 91 of the substrate 9 is, e.g., about 0.5 to 1 liter per minute. Since the lower surface of the top plate 123 is close to the upper surface 91 of the substrate 9, the etching of the substrate 9 is performed in a very narrow space between the lower surface of the top plate 123 and the upper surface 91 of the substrate 9.

In the enlarged sealed space 100, the chemical liquid scattered from the upper surface 91 of the substrate 9 being rotated is received by the cup part 161 through the annular opening 81 and led toward the liquid receiving recessed portion 165. The chemical liquid led to the liquid receiving recessed portion 165 flows into the gas-liquid separating part 193 through the first exhaust path 191 shown in FIG. 4. In the chemical liquid collecting part 195, the chemical liquid is collected from the gas-liquid separating part 193, and after removing impurities or the like from the chemical liquid through a filter or the like, the chemical liquid is reused.

After a predetermined time (e.g., 60 to 120 seconds) elapses from the start of the supply of the chemical liquid from the upper nozzle 181, the supply of the chemical liquid from the upper nozzle 181 and the supply of the heating liquid from the heating liquid supply nozzles 180b are stopped. In each heating liquid supply nozzle 180b, the heating liquid is drawn back to the inside of the heating liquid supply nozzle 180b from the discharge port 1805 by suck back. It is thereby possible to suppress or prevent the flow of the heating liquid dripping from the discharge port 1805 into the heating gas supply nozzle 180a. Then, the substrate rotating mechanism 15 increases the number of rotation of the substrate 9 to be higher than the steady number of rotation for a predetermined time period (e.g., 1 to 3 seconds), to thereby remove the chemical liquid from the substrate 9.

Subsequently, when the chamber cover 122 and the cup part 161 synchronously moves down. Then, as shown in FIG. 9, a lip seal 231 positioned at the lower end of the outer edge portion of the chamber cover 122 comes into contact with an upper portion of the chamber sidewall 214, to thereby close the annular opening 81, and the chamber space 120 becomes sealed, being isolated from the side space 160. The cup part 161 is located at the escape position like in the state of FIG. 1. Hereinafter, the state of the chamber 12 and the cup part 161 shown in FIG. 9 is referred to as a “second sealed state”. In the second sealed state, the substrate 9 directly faces an inner wall of the chamber 12, and there is not any other liquid receiving part therebetween.

Also in the second sealed state, like in the first sealed state, the substrate retaining part 142 presses the substrate 9 toward the substrate supporting part 141, and it is thereby possible to strongly hold the substrate 9 being sandwiched from above and below by the substrate retaining part 142 and the substrate supporting part 141. Further, the plate holding part 222 releases holding of the top plate 123, and the top plate 123, being independent of the chamber cover 122, is rotated together with the substrate holding part 14 and the substrate 9.

After the chamber space 120 becomes sealed, the exhaust of the gas by the outer gas exhaust part 194 (see FIG. 4) is stopped and the exhaust of gas from the chamber space 120 by the inner gas exhaust part 198 is started. Then, the supply of the deionized water serving as a rinse liquid or a cleaning solution onto the substrate 9 is started by the deionized water supply part 184 (Step S13).

The deionized water from the deionized water supply part 184 is discharged from the upper nozzle 181 and the lower nozzle 182 and continuously supplied onto the respective center portions of the upper surface 91 and the lower surface 92 of the substrate 9. With the rotation of the substrate 9, the deionized water spreads toward the respective outer peripheral portions of the upper surface 91 and the lower surface 92 and is scattered outward from the outer peripheral edge of the substrate 9. The deionized water scattered from the substrate 9 is received by the inner wall of the chamber 12 (i.e., the respective inner walls of the chamber cover 122 and the chamber sidewall 214) and discarded through the second exhaust path 192, the gas-liquid separating part 197, and the liquid exhaust part 199 shown in FIG. 2 (the same applies to a drying process on the substrate 9 described later). With this operation, as well as a rinse process and a cleaning process on the upper surface 91 and the lower surface 92 of the substrate 9, cleaning of the inside of the chamber 12 is substantially performed.

After a predetermined time elapses from the start of supply of the deionized water, the supply of the deionized water from the deionized water supply part 184 is stopped. Then, under the control by the control part 10, the ejection of the inert gas (i.e., the heating gas) heated to a temperature higher than that of the substrate 9 is started from the respective heating gas supply nozzles 180a of the plurality of supply nozzles 180 toward the lower surface 92 of the substrate 9. The heating gas from each heating gas supply nozzle 180a is continuously ejected toward the lower surface 92 of the substrate 9 between the central axis J1 and the outer peripheral edge of the substrate 9. The heating gas ejected onto the lower surface 92 of the substrate 9 from the heating gas supply nozzle 180a spreads toward a space below the substrate 9. The substrate 9 is thereby heated. The temperature of the heating gas is, e.g., about 160 to 200° C. Further, the total flow rate of the heating gas to be supplied from the plurality of heating gas supply nozzles 180a is, e.g., about 150 to 200 liters per minute. In each supply nozzle 180, even in a case where the heating liquid is deposited and remains in the vicinity of the discharge port 1805 of the heating liquid supply nozzle 180b, the heating liquid is blown away and removed by the heating gas from the heating gas supply nozzle 180a.

Subsequently, the IPA is supplied onto the upper surface 91 of the substrate 9 from the upper nozzle 181, and the deionized water is replaced with the IPA on the upper surface 91 (Step S14). After a predetermined time elapses from the start of supply of the IPA, the supply of the IPA from the IPA supply part 185 is stopped. After that, while the ejection of the heating gas from the heating gas supply nozzles 180a continues, the number of rotation of the substrate 9 is increased to be sufficiently higher than the steady number of rotation. The IPA is thereby removed from the substrate 9, and drying of the substrate 9 is performed (Step 15). After a predetermined time elapses from the start of drying of the substrate 9, the rotation of the substrate 9 is stopped. The drying of the substrate 9 may be performed in a reduced pressure atmosphere in which the pressure of the chamber space 120 is reduced by the inner gas exhaust part 198 to be lower than the atmosphere pressure.

After that, the chamber cover 122 and the top plate 123 move up, and the chamber 12 is brought into the open state as shown in FIG. 1. In Step S15, since the top plate 123 is rotated together with the substrate supporting part 141, almost no liquid remains on the lower surface of the top plate 123 and therefore, no liquid drops from the top plate 123 onto the substrate 9 when the chamber cover 122 moves up. The substrate 9 is unloaded from the chamber 12 by the external transfer mechanism (Step S16).

As described above, in the substrate processing apparatus 1, provided are the upper nozzle 181 for supplying the chemical liquid having a temperature higher than that of the substrate 9 onto the upper surface 91 of the substrate 9 and the heating liquid supply nozzles 180b for supplying the heating liquid having a temperature higher than that of the substrate 9 onto the lower surface 92 of the substrate 9 between the central axis J1 and the outer peripheral edge of the substrate 9. It is thereby possible to suppress or prevent a decrease in the temperature of the substrate 9 and the temperature of the chemical liquid supplied onto the upper surface 91 of the substrate 9 from the center portion of the substrate 9 toward the outer peripheral portion thereof. As a result, it is possible to improve the uniformity of the temperature of the substrate 9 and the temperature of the chemical liquid on the substrate 9, and also improve the inplane uniformity of the etching on the upper surface 91 of the substrate 9. Further, the etching of the lower surface 92 of the substrate 9 by using the heating liquid can be performed concurrently with the etching of the upper surface 91.

Thus, in the substrate processing apparatus 1, it is possible to improve the uniformity of the temperature of the substrate 9 and the temperature of the chemical liquid on the substrate 9. For this reason, the constitution of the substrate processing apparatus 1 is especially suitable for a substrate processing apparatus in which the temperature of the chemical liquid supplied onto the upper surface 91 of the substrate 9 is relatively easy to decrease from the center portion of the substrate 9 toward the outer peripheral portion thereof, e.g., a substrate processing apparatus in which the upper nozzle 181 for discharging the chemical liquid onto the upper surface 91 of the substrate 9 is so fixed as to face the center portion of the upper surface 91. In the substrate processing apparatus in which the upper nozzle 181 is so fixed as to face the center portion of the upper surface 91 of the substrate 9, since a moving distance of the chemical liquid supplied on the upper surface 91, which travels on the substrate 9, until the chemical liquid is scattered from the outer edge is long, it is possible to efficiently use the chemical liquid supplied on the upper surface 91 for the etching process.

In the substrate processing apparatus 1, the heating gas supply nozzles 180a for supplying the heating gas having a temperature higher than that of the substrate 9 toward the lower surface 92 of the substrate 9 between the central axis J1 and the outer peripheral edge of the substrate 9 are further provided. Since the substrate 9 can be thereby heated without supplying any liquid to the substrate 9 in drying the substrate 9, it is possible to increase the volatility of the IPA on the substrate 9. As a result, it is possible to quickly dry the substrate 9 and suppress or prevent any damage of the fine pattern on the upper surface 91 of the substrate 9 in drying the substrate 9.

Further, in the substrate processing apparatus 1, the heating gas supply nozzle 180a and the heating liquid supply nozzle 180b constitute one supply nozzle 180. It is thereby possible to simplify and downsize the structure used for heating the lower surface 92 of the substrate 9 in the chemical liquid processing and the drying of the substrate 9. As a result, it is possible to effectively use a space between the substrate 9 and the chamber bottom 210 (i.e., the space below the substrate 9).

In the substrate processing apparatus 1, two or more heating liquid supply nozzles 180b among the plurality of heating liquid supply nozzles 180b are positioned on the same circumference around the central axis J1. It is thereby possible to reduce the time after each portion of the substrate 9 above the circle passes above the heating liquid supply nozzle 180b to be supplied with the heating liquid until the portion moves to above the next heating liquid supply nozzle 180b. It is further thereby possible to suppress a decrease in the temperature while each portion of the substrate 9 moves between the heating liquid supply nozzles 180b (in other words, a decrease in the temperature during rotation). As a result, it is possible to improve the uniformity of the temperature of the substrate 9 and the temperature of the chemical liquid on the substrate 9 in the circumferential direction in performing the chemical liquid processing on the substrate 9 and further improve the inplane uniformity of the etching on the substrate 9.

As mentioned above, the chemical liquid supplied onto the upper surface 91 of the substrate 9 from the upper nozzle 181 and the heating liquid supplied onto the lower surface 92 of the substrate 9 from the heating liquid supply nozzles 180b are the same liquid supplied from one chemical liquid supply part 183. The liquid (chemical liquid) is heated by one liquid heating part 188 before being supplied to the upper nozzle 181 and the heating liquid supply nozzles 180b. It is thereby possible to simplify the structure of the substrate processing apparatus 1 and downsize the substrate processing apparatus 1.

In the substrate processing apparatus 1, two or more heating gas supply nozzles 180a among the plurality of heating gas supply nozzles 180a are positioned on the same circumference around the central axis J1. It is thereby possible to reduce the time after each portion of the substrate 9 above the circle passes above the heating gas supply nozzle 180a to be supplied with the heating gas until the portion moves to above the next heating gas supply nozzle 180a. It is further thereby possible to suppress a decrease in the temperature while each portion of the substrate 9 moves between the heating gas supply nozzles 180a (in other words, a decrease in the temperature during rotation). As a result, it is possible to improve the uniformity of the temperature of the substrate 9 in the circumferential direction in drying the substrate 9 and more quickly dry the substrate 9. Further, it is possible to much further suppress or prevent any damage of the fine pattern on the upper surface 91 of the substrate 9 in drying the substrate 9.

In the substrate processing apparatus 1, the supply nozzles 180 protrude from the facing surface 211a of the lower surface facing part 211. It is thereby possible to suppress the flow of the processing liquid such as deionized water or the like which is supplied onto the lower surface 92 of the substrate 9 from the lower nozzle 182 into the heating gas supply nozzles 180a from the ejection ports 1802 and the heating liquid supply nozzles 180b from the discharge ports 1805. Further, since the supply nozzles 180 are each inclined with respect to the central axis J1, it is possible to much further suppress the flow of the processing liquid such as deionized water or the like into the heating gas supply nozzles 180a and the heating liquid supply nozzles 180b.

As described above, the facing surface 211a of the lower surface facing part 211 is a sloped surface which gets farther away from the substrate 9 as a distance from the central axis J1 becomes larger. It is thereby possible to easily guide the processing liquid such as the chemical liquid, the deionized water, or the like which is supplied onto the lower surface 92 of the substrate 9 toward the outer side of the facing surface 211a in the radial direction. As a result, it is also possible to prevent the processing liquid from being accumulated on the facing surface 211a.

FIG. 10 is a graph showing a temperature distribution of the substrate 9 in performing the chemical liquid processing (Step S12) in the substrate processing apparatus 1 while supplying the heating liquid onto the lower surface 92 of the substrate 9 in the substrate processing apparatus 1. FIG. 10 shows the temperature distribution of the substrate 9 having a radius of about 150 mm. In FIG. 10, the horizontal axis represents a distance between each measurement position and the central axis J1 in the radial direction and the vertical axis represents a temperature of the substrate 9 at the measurement position. The same applies to FIGS. 11 and 13. In FIG. 10, a solid line with reference sign “95” represents a temperature of the substrate 9 in performing the chemical liquid processing in the substrate processing apparatus 1 and a black circle represents a temperature of a substrate in performing the chemical liquid processing in a substrate processing apparatus of a first comparative example. In the substrate processing apparatus of the first comparative example, no heating liquid supply nozzle is provided, and a chemical liquid having a temperature higher than that of the substrate is supplied onto an upper surface of the substrate from an upper nozzle and no heating liquid is supplied onto a lower surface of the substrate. The temperature of the substrate 9 indicated by the solid line 95 is estimated by simulation from an experimental result obtained in a substrate processing apparatus in which the heating gas supply nozzles 180a and the heating liquid supply nozzles 180b are separately disposed on the lower surface facing part 211 (the same applies to solid lines 96 to 98 in FIGS. 11 and 13). As shown in FIG. 10, in the substrate processing apparatus 1, as compared with in the substrate processing apparatus of the first comparative example, it is possible to suppress a decrease in the temperature of the substrate 9 from the center portion of the substrate 9 toward the outer peripheral portion thereof.

In the substrate processing apparatus 1, in a case where the chemical liquid processing on the lower surface 92 of the substrate 9 is not performed in performing the chemical liquid processing on the upper surface 91 of the substrate 9, instead of supplying the heating liquid from the heating liquid supply nozzles 180b, the heating gas may be supplied onto the lower surface 92 of the substrate 9 from the heating gas supply nozzles 180a concurrently with supplying the chemical liquid from the upper nozzle 181. FIG. 11 is a graph showing a temperature distribution of the substrate 9 in performing the chemical liquid processing (Step S12) in the case where the heating gas is supplied onto the lower surface 92 of the substrate 9 instead of the heating liquid. In FIG. 11, a solid line with reference sign “96” represents a temperature of the substrate 9 in performing the chemical liquid processing in the substrate processing apparatus 1 and a black circle represents a temperature of the substrate in performing the chemical liquid processing in the substrate processing apparatus of the above-described first comparative example. As shown in FIG. 11, also in the case where the heating gas is supplied onto the lower surface 92 of the substrate 9 in performing the chemical liquid processing, it is possible to suppress a decrease in the temperature of the substrate 9 from the center portion of the substrate 9 toward the outer peripheral portion thereof as compared with in the substrate processing apparatus of the first comparative example.

Assuming that a substrate processing apparatus in which a substrate is processed in an open processing space is considered as a comparative example (hereinafter, referred to as a “substrate processing apparatus of a second comparative example”), in the substrate processing apparatus of the second comparative example, in order to prevent diffusion of the gas containing a chemical liquid component to the outside, the gas is exhausted in a high flow rate from the processing space during the processing of the substrate by using the chemical liquid. Further, in order to prevent deposition of particles on the substrate, a downflow is formed. Therefore, an airflow from upper toward lower is formed around the substrate, and the temperature of the substrate becomes easy to decrease due to the airflow. The decrease in the temperature of the substrate becomes more remarkable at an outer edge portion of the substrate, and the uniformity of the temperature distribution of the substrate is deteriorated. As a result, the uniformity of the processing of the substrate by using the chemical liquid is deteriorated. Though it may be possible to suppress deterioration in the uniformity of the temperature distribution of the substrate by supplying the chemical liquid which is heated to a certain temperature onto the substrate in a high flow rate, the amount of chemical liquid consumed disadvantageously increases.

On the other hand, in the substrate processing apparatus 1, the enlarged sealed space 100 which is a sealed space smaller than the processing space in the substrate processing apparatus of the second comparative example is formed by the chamber 12, the cup part 161, and the cup facing part 163 which serve as the sealed space forming part. It is thereby possible to suppress diffusion of heat from the substrate 9.

In the substrate processing apparatus 1 in which the enlarged sealed space 100 is formed, since the gas containing the chemical liquid component is not diffused outside and there is low necessity of the downflow which is formed in order to prevent deposition of particles on the substrate, it is possible to set the amount of gas flowing into the enlarged sealed space 100 and the amount of gas flowing out of the enlarged sealed space 100 low. Therefore, it is possible to further reduce the decrease in the temperature of the substrate 9. As a result, it is possible to improve the uniformity of the temperature distribution of the substrate while setting the flow rate of the heating liquid from the heating liquid supply nozzles 180b relatively low. Further, since it is not necessary to supply the chemical liquid which is heated to a certain temperature onto the upper surface 91 of the substrate 9 in a high flow rate (in other words, it is possible to reduce the amount of chemical liquid consumed), it is possible to also reduce the COO (Cost Of Ownership) of the substrate processing apparatus 1.

In the substrate processing apparatus 1, in performing the above-described chemical liquid processing, Step S121 shown in FIG. 12 may be executed instead of Step S12. In Step S121, under the control by the control part 10, the heated chemical liquid is supplied onto the upper surface 91 of the substrate 9 being rotated from the upper nozzle 181, and concurrently with the supply of the chemical liquid, the heating liquid is supplied onto the lower surface 92 of the substrate 9 from the heating liquid supply nozzles 180b, like in Step S12. In Step S121, concurrently with the supply of the chemical liquid from the upper nozzle 181 and the supply of the heating liquid from the heating liquid supply nozzles 180b, the heating gas is further supplied into a space below the substrate 9 from the heating gas supply nozzles 180a.

The supply of the heating gas into the space below the substrate 9 from the heating gas supply nozzles 180a is performed more gently than the ejection of the heating gas from the heating gas supply nozzles 180a in the above-described drying process on the substrate 9 (Step S15). For this reason, it is possible to prevent the heating liquid supplied onto the lower surface 92 of the substrate 9 from the heating liquid supply nozzles 180b from being flicked off the lower surface 92 by the heating gas from the heating gas supply nozzles 180a and the flow of the heating liquid running on the lower surface 92 from being disturbed by the heating gas from the heating gas supply nozzles 180a.

In Step S121, in a heating gas atmosphere where high-temperature heating gas is supplied into the space below the substrate 9, the heating liquid from the heating liquid supply nozzles 180b is supplied onto the lower surface 92 of the substrate 9 and moved on the lower surface 92 toward the outer peripheral portion. It is thereby possible to suppress a decrease in the temperature of the heating liquid during periods while the heating liquid is supplied onto the substrate 9 and moved on the substrate 9.

As described above, in each supply nozzle 180, as shown in FIGS. 2 and 3, provided is the inner peripheral wall 801 which is a partition wall shared by the heating gas supply nozzle 180a and the heating liquid supply nozzle 180b, and the temperature (about 160 to 200° C.) of the heating gas is higher than the temperature (about 50 to 80° C.) of the heating liquid. For this reason, the heating liquid flowing in the heating liquid supply nozzle 180b is heated by the heating gas flowing in the heating gas supply nozzle 180a through the inner peripheral wall 801. It is thereby possible to suppress a decrease in the temperature of the heating liquid delivered from the liquid heating part 188 until the heating liquid is supplied onto the lower surface 92 of the substrate 9.

In order to efficiently heat the heating liquid by the heating gas through the inner peripheral wall 801, it is preferable that the length of a portion of the inner peripheral wall 801 which comes into direct contact with the heating liquid and the heating gas in the heating gas supply nozzle 180a in a longitudinal direction (in other words, the length in a direction parallel to the central axis J2 of the supply nozzle 180, which is equal to the length of the outer peripheral wall 802 in the longitudinal direction) should be not shorter than 50 mm. Further, since the supply nozzle 180 is a double tube in which the heating gas supply nozzle 180a surrounds the periphery of the heating liquid supply nozzle 180b all around the circumference, it is possible to more efficiently heat the heating liquid by the heating gas through the inner peripheral wall 801 and improve the uniformity of the temperature of the heating liquid in the heating liquid supply nozzle 180b.

As described above, in the supply nozzle 180 which is a double tube, the heating liquid supply nozzle 180b is disposed on the inner side of the heating gas supply nozzle 180a. It is thereby possible to suppress the flow of the heating liquid to be discharged from the heating liquid supply nozzle 180b from being disturbed by the heating gas to be ejected from the heating gas supply nozzle 180a. Further, the discharge port 1805 of the heating liquid supply nozzle 180b and a portion of the inner peripheral wall 801 in the vicinity of the discharge port 1805 protrude than the ejection port 1802 of the heating gas supply nozzle 180a. For this reason, it is possible to further suppress the flow of the heating liquid to be discharged from the heating liquid supply nozzle 180b from being disturbed by the heating gas to be ejected from the heating gas supply nozzle 180a.

In the lower surface facing part 211, the periphery of each heating liquid pipe 806 is surrounded by the heating gas pipe 808 all around the circumference, and the heating liquid pipe 806 serves as a partition wall which comes into direct contact with the heating liquid and the heating gas in the heating gas pipe 808. For this reason, the heating liquid flowing in the heating liquid pipe 806 is heated by the heating gas flowing in the heating gas pipe 808 through the heating liquid pipe 806. It is thereby possible to further suppress a decrease in the temperature of the heating liquid delivered from the liquid heating part 188 until the heating liquid is supplied onto the lower surface 92 of the substrate 9. In order to efficiently heat the heating liquid in the heating liquid pipe 806 by the heating gas, it is preferable that a portion of the heating liquid pipe 806 which is positioned away from the facing surface 211a toward the liquid heating part 188 by at least about 20 to 30 centimeters should come into direct contact with the heating liquid and the heating gas in the heating gas pipe 808.

In the lower surface facing part 211, the heating liquid manifold 807 connected to the plurality of heating liquid pipes 806 is further provided, and the outer surface of the heating liquid manifold 807 is covered with the heating gas manifold 809. Therefore, a sidewall of the heating liquid manifold 807 comes into direct contact with the heating liquid in the heating liquid manifold 807 and the heating gas in the heating gas manifold 809. The heating liquid in the heating liquid manifold 807 is thereby heated by the heating gas through the sidewall of the heating liquid manifold 807. It is thereby possible to further suppress a decrease in the temperature of the heating liquid delivered from the liquid heating part 188 until the heating liquid is supplied onto the lower surface 92 of the substrate 9. In order to efficiently heat the heating liquid in the heating liquid manifold 807 by the heating gas, it is preferable that almost the entire sidewall of the heating liquid manifold 807 should come into direct contact with the heating gas. From the viewpoint of heating of the heating liquid in the heating liquid manifold 807 by the heating gas, at least part of the sidewall of the heating liquid manifold 807 may come into direct contact with the heating gas.

Further, by once pooling the heating liquid from the liquid heating part 188 in the heating liquid manifold 807 and then supplying the heating liquid from the heating liquid manifold 807 to the plurality of heating liquid supply nozzles 180b, it is possible to improve the uniformity of the temperature of the heating liquid to be supplied from the plurality of the heating liquid supply nozzles 180b onto the lower surface 92 of the substrate 9.

As mentioned above, the chemical liquid supplied onto the upper surface 91 of the substrate 9 from the upper nozzle 181 and the heating liquid supplied onto the lower surface 92 of the substrate 9 from the heating liquid supply nozzles 180b are the same liquid. In the substrate processing apparatus 1, it is possible not only to simplify the apparatus structure by heating the liquid by one liquid heating part 188, but also to make the temperature of the heating liquid supplied onto the lower surface 92 of the substrate 9 from the heating liquid supply nozzles 180b higher than the temperature of the chemical liquid supplied onto the upper surface 91 of the substrate 9 from the upper nozzle 181 by heating the heating liquid in the heating liquid manifold 807, the heating liquid pipes 806, and the heating liquid supply nozzles 180b by the heating gas. As a result, it is possible to much further suppress or prevent a decrease in the temperature of the substrate 9 and the temperature of the chemical liquid supplied onto the upper surface 91 of the substrate 9 from the center portion of the substrate 9 toward the outer peripheral portion thereof. It is consequently possible to improve the uniformity of the temperature of the substrate 9 and the temperature of the chemical liquid on the substrate 9 and also improve the inplane uniformity of the etching on the upper surface 91 of the substrate 9.

FIG. 13 is a graph showing a temperature distribution of the substrate 9 in performing the chemical liquid processing (Step S121) while the heating liquid is supplied onto the lower surface 92 of the substrate 9 and the heating gas is supplied into the space below the lower surface 92 in the substrate processing apparatus 1. In FIG. 13, solid lines with reference signs “97” and “98” represent an upper limit estimated value and a lower limit estimated value of a temperature of the substrate 9 in performing the chemical liquid processing in the substrate processing apparatus 1 and a black circle represents a temperature of the substrate in performing the chemical liquid processing in the substrate processing apparatus of the above-described first comparative example. As shown in FIG. 13, a decrease in the temperature of the substrate 9 from the center portion of the substrate 9 toward the outer peripheral portion thereof is suppressed in the substrate processing apparatus 1, as compared with in the substrate processing apparatus of the first comparative example.

FIGS. 14 and 15 are plan views each showing another exemplary arrangement of the supply nozzles 180 on the lower surface facing part 211 in the substrate processing apparatus 1. Also in the examples of FIGS. 14 and 15, six supply nozzles 180 are provided at the respective attachment positions 1801 on the lower surface facing part 211. Assuming that two supply nozzles 180 which have the same distance from the central axis J1 in the radial direction is referred to as a “nozzle pair”, in the example of FIG. 14, three nozzle pairs of the supply nozzles 180 are provided on the lower surface facing part 211. Two supply nozzles 180 in each nozzle pair are disposed at facing positions with the central axis J1 as the center on the same circumference around the central axis J1. In other words, two supply nozzles 180 in each nozzle pair are disposed at an interval of 180 degrees in the circumferential direction around the central axis J1. The six supply nozzles 180 are disposed at regular angular intervals (at intervals of 60 degrees) in the circumferential direction.

In the example of FIG. 15, two supply nozzles 180 are disposed at facing positions with the central axis J1 as the center on the same circumference around the central axis J1. The other four supply nozzles 180 are disposed outer than the above two supply nozzles 180 in the radial direction on the same circumference around the central axis J1. The four supply nozzles 180 are disposed at regular angular intervals (at intervals of 90 degrees) in the circumferential direction.

In the examples of FIGS. 14 and 15, provided are the plurality of supply nozzles 180 (i.e., the heating gas supply nozzles 180a and the heating liquid supply nozzles 180b) having different distances from the central axis J1 in the radial direction. In other words, a distance between one supply nozzle 180 among the plurality of supply nozzles 180 and the central axis J1 in the radial direction is different from that between another supply nozzle 180 and the central axis J1 in the radial direction. For this reason, since the lower surface 92 of the substrate 9 is heated by the heating liquid from the heating liquid supply nozzle 180b of each supply nozzle 180, it is possible to much further suppress or prevent a decrease in the temperature of the chemical liquid supplied onto the upper surface 91 of the substrate 9 from the center portion of the substrate 9 toward the outer peripheral portion thereof. Also in the case where the lower surface 92 of the substrate 9 is heated by the heating gas from the heating gas supply nozzle 180a of each supply nozzle 180, it is possible to much further suppress or prevent a decrease in the temperature of the chemical liquid supplied onto the upper surface 91 of the substrate 9 from the center portion of the substrate 9 toward the outer peripheral portion thereof. In both cases, it is possible to improve the uniformity of the temperature of the substrate 9 and the temperature of the chemical liquid on the substrate 9 in the radial direction and further improve the inplane uniformity of the etching on the upper surface 91 of the substrate 9.

FIG. 16 is a cross-sectional view showing a substrate processing apparatus lain accordance with the second preferred embodiment of the present invention. The substrate processing apparatus 1a is a single-substrate processing apparatus for supplying a processing liquid to a semiconductor substrate 9 (hereinafter, referred to simply as a “substrate 9”) having a substantially disk-like shape, to thereby process substrates 9 one by one. In the substrate processing apparatus 1a of FIG. 16, the structure and the arrangement of nozzles provided on the lower surface facing part 211 are different from those in the substrate processing apparatus 1 of FIG. 1. Other constituent elements in the substrate processing apparatus 1a are almost identical to those in the substrate processing apparatus 1, and the corresponding constituent elements will be represented by the same reference signs in the following description. In FIG. 16, hatching of the cross sections of some constituent elements in the substrate processing apparatus 1a is omitted (the same applies to other cross-sectional views).

At the center portion of the lower surface facing part 211 of the chamber bottom 210, the lower nozzle 182 is attached. The lower nozzle 182 has a liquid discharge port at its center portion and faces the center portion of the lower surface 92 of the substrate 9. On the lower surface facing part 211, the plurality of heating gas supply nozzles 180a and the plurality of heating liquid supply nozzles 180b are further provided. The arrangement of the heating gas supply nozzles 180a and the heating liquid supply nozzles 180b will be described later.

FIG. 17 is a block diagram showing the gas-liquid supply part 18 and the gas-liquid exhaust part 19 included in the substrate processing apparatus 1a. The gas-liquid supply part 18 includes the chemical liquid supply part 183, the deionized water supply part 184, the IPA supply part 185, the inert gas supply part 186, the heating gas supply part 187, and the liquid heating part 188, besides the heating gas supply nozzles 180a, the heating liquid supply nozzles 180b, the upper nozzle 181, and the lower nozzle 182 described above.

The chemical liquid supply part 183 is connected to the liquid heating part 188, and the liquid heating part 188 is connected to the upper nozzle 181 with a valve interposed therebetween and also to the plurality of heating liquid supply nozzles 180b with a valve interposed therebetween. A chemical liquid supplied from the chemical liquid supply part 183 to the liquid heating part 188 is heated in the liquid heating part 188. The heated chemical liquid is supplied to the upper nozzle 181 and the plurality of heating liquid supply nozzles 180b. The start and stop of the supply of the chemical liquid to the upper nozzle 181 and the start and stop of the supply of the chemical liquid to the heating liquid supply nozzles 180b can be individually controlled by the control part 10.

The deionized water supply part 184 and the IPA supply part 185 are connected to the upper nozzle 181 each with a valve interposed therebetween. The lower nozzle 182 is connected to the deionized water supply part 184 with a valve interposed therebetween. The upper nozzle 181 is also connected to the inert gas supply part 186 with a valve interposed therebetween. The upper nozzle 181 is part of a gas supply part for supplying gas into the chamber 12. The plurality of heating gas supply nozzles 180a are connected to the heating gas supply part 187 with a valve interposed therebetween.

The first exhaust path 191 connected to the liquid receiving recessed portion 165 of the liquid receiving part 16 is connected to the gas-liquid separating part 193. The gas-liquid separating part 193 is connected to the outer gas exhaust part 194, the chemical liquid collecting part 195, and the liquid exhaust part 196 each with a valve interposed therebetween. The second exhaust path 192 connected to the chamber bottom 210 of the chamber 12 is connected to the gas-liquid separating part 197. The gas-liquid separating part 197 is connected to the inner gas exhaust part 198 and the liquid exhaust part 199 each with a valve interposed therebetween. The constituent elements in the gas-liquid supply part 18 and the gas-liquid exhaust part 19 are controlled by the control part 10. The chamber opening and closing mechanism 131, the substrate rotating mechanism 15, and the cup moving mechanism 162 (see FIG. 16) are also controlled by the control part 10.

A chemical liquid supplied from the chemical liquid supply part 183 onto the substrate 9 through the upper nozzle 181 and the plurality of heating liquid supply nozzles 180b is a processing liquid to be used for processing the substrate by utilizing chemical reaction, which is, for example, an etching solution such as hydrofluoric acid, a tetramethylammonium hydroxide solution, or the like. The deionized water supply part 184 supplies deionized water (DIW) onto the substrate 9 through the upper nozzle 181 or the lower nozzle 182. The IPA supply part 185 supplies isopropyl alcohol (IPA) onto the substrate 9 through the upper nozzle 181. In the substrate processing apparatus 1a, a processing liquid supply part for supplying any processing liquid other than the above processing liquids (the above-described chemical liquid, deionized water, and IPA) may be provided.

The inert gas supply part 186 supplies an inert gas into the chamber 12 through the upper nozzle 181. The heating gas supply part 187 supplies heated gas (e.g., a high-temperature inert gas) onto the lower surface 92 of the substrate 9 through the plurality of heating gas supply nozzles 180a. In the present preferred embodiment, the gas used in the inert gas supply part 186 and the heating gas supply part 187 is nitrogen gas (N₂), but any gas other than nitrogen gas may be used. Further, in the case where the heated inert gas is used in the heating gas supply part 187, the explosion-proof countermeasure in the substrate processing apparatus 1a can be simplified or is not needed.

FIG. 18 is a plan view showing an arrangement of the plurality of heating gas supply nozzles 180a and the plurality of heating liquid supply nozzles 180b on the lower surface facing part 211 of the chamber bottom 210. In FIG. 18, the whole of each heating gas supply nozzle 180a is not shown, and an attachment position of each heating gas supply nozzle 180a on the lower surface facing part 211 is represented by a solid-line circle with reference number “1801”. Further, the whole of each heating liquid supply nozzle 180b is not shown, and an attachment position of each heating liquid supply nozzle 180b is represented by a solid-line circle with reference number “1804”.

As shown in FIG. 18, six heating gas supply nozzles 180a are provided on the lower surface facing part 211. Assuming that two heating gas supply nozzles 180a which have the same distance from the central axis J1 in the radial direction is referred to as a “nozzle pair”, three nozzle pairs of the heating gas supply nozzles 180a are provided on the lower surface facing part 211. Two heating gas supply nozzles 180a in each nozzle pair are disposed at facing positions with the central axis J1 as the center on the same circumference around the central axis J1. In other words, two heating gas supply nozzles 180a in each nozzle pair are disposed at an interval of 180 degrees in the circumferential direction around the central axis J1. The six heating gas supply nozzles 180a are disposed at regular angular intervals (at intervals of 60 degrees) in the circumferential direction. In FIG. 16, the six heating gas supply nozzles 180a are shown on the same cross section (the same applies to FIGS. 19, 20, and 21).

On the lower surface facing part 211, six heating liquid supply nozzles 180b are also provided. Two heating liquid supply nozzles 180b are disposed at facing positions with the central axis J1 as the center on the same circumference around the central axis J1. The other four heating liquid supply nozzles 180b are disposed outer than the above two heating liquid supply nozzles 180b in the radial direction on the same circumference around the central axis J1. The four heating liquid supply nozzles 180b are disposed at regular angular intervals (at intervals of 90 degrees) in the circumferential direction.

In the substrate processing apparatus 1a used for processing the substrate 9 having a radius of about 150 mm, for example, a distance between the center of an ejection port of each heating gas supply nozzle 180a in the nozzle pair which is closest to the central axis J1 and the central axis J1 (hereinafter, referred to as an “ejection port-central axis distance”) is about 65 mm. The ejection port-central axis distance of each heating gas supply nozzle 180a in the nozzle pair which is second closest to the central axis J1 is about 95 mm. The ejection port-central axis distance of each heating gas supply nozzle 180a in the nozzle pair which is farthest from the central axis J1 is about 145 mm. Further, a distance between the center of a discharge port of each of the two heating liquid supply nozzles 180b which are closer to the central axis J1 and the central axis J1 (hereinafter, referred to as a “discharge port-central axis distance”) is about 60 mm. The discharge port-central axis distance of each of the four heating liquid supply nozzles 180b which are farther from the central axis J1 is about 120 mm.

FIG. 19 is an enlarged cross-sectional view showing the vicinity of the lower surface facing part 211. As shown in FIG. 19, when the substrate 9 is supported by the substrate supporting part 141, the facing surface 211a of the lower surface facing part 211 faces the lower surface 92 of the substrate 9 on the inner side of the substrate supporting part 141 in the radial direction. The facing surface 211a is a sloped surface which goes downward (in other words, gets farther away from the substrate 9) as a distance from the central axis J1 becomes larger, extending almost entirely over the lower surface 92 of the substrate 9. A distance between the facing surface 211a and the lower surface 92 of the substrate 9 becomes minimum in the vicinity of the lower nozzle 182, and is, e.g., 5 mm. Further, the distance becomes maximum at the outer edge portion of the substrate 9, and is, e.g., 30 mm.

Each heating gas supply nozzle 180a and each heating liquid supply nozzle 180b protrude from the facing surface 211a. Each heating gas supply nozzle 180a is connected to the heating gas supply part 187 (see FIG. 17) through a heating gas pipe (not shown) formed inside the lower surface facing part 211. Each heating liquid supply nozzle 180b is connected to the liquid heating part 188 through a heating liquid pipe (not shown) formed inside the lower surface facing part 211.

The ejection port 1802 of each heating gas supply nozzle 180a and the discharge port 1805 of each heating liquid supply nozzle 180b are close to the lower surface 92 of the substrate 9 above the facing surface 211a. Each heating gas supply nozzle 180a is fixed to the lower surface facing part 211 so that its central axis may extend almost along the normal of the facing surface 211a at the attachment position 1801. Each heating liquid supply nozzle 180b is also fixed to the lower surface facing part 211 so that its central axis may extend almost along the normal of the facing surface 211a at the attachment position 1804. Therefore, each heating gas supply nozzle 180a is inclined with respect to the central axis J1 so that the ejection port 1802 may be positioned slightly outer than the attachment position 1801 in the radial direction. Further, each heating liquid supply nozzle 180b is inclined with respect to the central axis J1 so that the discharge port 1805 may be positioned slightly outer than the attachment position 1804 in the radial direction.

An operation flow for processing the substrate 9 in the substrate processing apparatus 1a is almost the same as that shown in FIG. 7. In the substrate processing apparatus 1a, in a state where the chamber cover 122 is separated from the chamber body 121 and positioned thereabove and the cup part 161 is separated from the chamber cover 122 and positioned therebelow as shown in FIG. 16, the substrate 9 is loaded into the chamber 12 by an external transfer mechanism and supported by the substrate supporting part 141 from below (Step S11). Hereinafter, the state of the chamber 12 and the cup part 161 shown in FIG. 16 is referred to as an “open state”. An opening between the chamber cover 122 and the chamber sidewall 214 has an annular shape around the central axis J1 and is hereinafter referred to as the “annular opening 81”. In the substrate processing apparatus 1a, when the chamber cover 122 is separated from the chamber body 121, the annular opening 81 is formed around the substrate 9 (in other words, outer than the substrate 9 in the radial direction). In Step S11, the substrate 9 is loaded through the annular opening 81.

After the substrate 9 is loaded, the cup part 161 moves upward from the position shown in FIG. 16 up to the position shown in FIG. 20, to be positioned outer than the annular opening 81 in the radial direction all around the circumference. In the following description, the state of the chamber 12 and the cup part 161 shown in FIG. 20 is referred to as a “first sealed state”. Further, the position of the cup part 161 shown in FIG. 20 is referred to as a “liquid receiving position” and the position of the cup part 161 shown in FIG. 16 is referred to as an “escape position”. The cup moving mechanism 162 moves the cup part 161 in the vertical direction between the liquid receiving position which is outer than the annular opening 81 in the radial direction and the escape position below the liquid receiving position.

In the cup part 161 positioned at the liquid receiving position, the sidewall 611 faces the annular opening 81 in the radial direction. Further, an upper surface of an inner edge portion of the upper surface part 612 is in contact with the lip seal 232 positioned at a lower end of an outer edge portion of the chamber cover 122 all around the circumference. Between the chamber cover 122 and the upper surface part 612 of the cup part 161, formed is a seal part for preventing the passage of gas and liquid. This forms a sealed internal space (hereinafter, referred to as the “enlarged sealed space 100”) surrounded by the chamber body 121, the chamber cover 122, the cup part 161, and the cup facing part 163.

The enlarged sealed space 100 is a space which is formed when the chamber space 120 between the chamber cover 122 and the chamber body 121 and the side space 160 surrounded by the cup part 161 and the cup facing part 163 communicate with each other through the annular opening 81. The chamber cover 122, the chamber body 121, the cup part 161, and the cup facing part 163 serves as a sealed space forming part which forms the enlarged sealed space 100.

In the first sealed state, the plurality of second contact parts 421 of the substrate retaining part 142 are in contact with the outer edge portion of the substrate 9. On the lower surface of the top plate 123 and on the supporting part base 413 of the substrate supporting part 141, provided are a plurality of pairs of magnets (not shown) in each of which two magnets face each other in the vertical direction. Hereinafter, each pair of magnets is referred to also as “a magnet pair”. In the substrate processing apparatus 1a, a plurality of magnet pairs are disposed at regular angular intervals at positions different from those of the first contact parts 411, the second contact parts 421, the first engagement parts 241, and the second engagement parts 242 in the circumferential direction. In a state where the substrate retaining part 142 is in contact with the substrate 9, with a magnetic force (attractive force) exerted between each magnet pair, a downward force is exerted on the top plate 123. The substrate retaining part 142 thereby presses the substrate 9 toward the substrate supporting part 141.

In the substrate processing apparatus 1a, the substrate retaining part 142 presses the substrate 9 toward the substrate supporting part 141 with the weight of the top plate 123 and the magnetic forces of the magnet pairs, and it is thereby possible to strongly hold the substrate 9 being sandwiched from above and below by the substrate retaining part 142 and the substrate supporting part 141.

In the first sealed state, the flange portion 239 of the held part 237 is separated above from the flange portion 224 of the plate holding part 222, and the plate holding part 222 is out of contact with the held part 237. In other words, the plate holding part 222 releases holding of the top plate 123. Therefore, the top plate 123, being independent of the chamber cover 122, is rotated by the substrate rotating mechanism 15, together with the substrate holding part 14 and the substrate 9 held by the substrate holding part 14.

Further, in the first sealed state, the second engagement part 242 engages with a lower recessed portion of the first engagement part 241. The top plate 123 thereby engages with the supporting part base 413 of the substrate supporting part 141 in the circumferential direction around the central axis J1. In other words, the first engagement part 241 and the second engagement part 242 serve as a position regulating member for regulating a relative position of the top plate 123 with respect to the substrate supporting part 141 in a rotation direction (in other words, for fixing a relative position in the circumferential direction). When the chamber cover 122 moves down, the substrate rotating mechanism 15 controls a rotation position of the supporting part base 413 so that the first engagement part 241 may engage with the second engagement part 242.

Subsequently, rotation of the substrate 9 is started by the substrate rotating mechanism 15 at a constant number of rotation (relatively low number of rotation, and hereinafter, referred to as “the steady number of rotation”). Further, the supply of the inert gas (herein, nitrogen gas) from the inert gas supply part 186 (see FIG. 17) into the enlarged sealed space 100 is started, and the exhaust of gas from the enlarged sealed space 100 by the outer gas exhaust part 194 is also started. After a predetermined time elapses, the enlarged sealed space 100 is thereby brought into an inert gas filled state where the inert gas is filled therein (in other words, into a low oxygen atmosphere where the oxygen concentration is low). Further, the supply of the inert gas into the enlarged sealed space 100 and the exhaust of the gas from the enlarged sealed space 100 may be performed in the open state shown in FIG. 16.

Next, under the control by the control part 10, the supply of the chemical liquid (i.e., a heating liquid) heated to a temperature higher than that of the substrate 9 is started toward the lower surface 92 of the substrate 9 from the plurality of heating liquid supply nozzles 180b. The heating liquid from each heating liquid supply nozzle 180b is continuously supplied onto the lower surface 92 of the substrate 9 between the central axis J1 and an outer peripheral edge of the substrate 9. With the rotation of the substrate 9, the heating liquid supplied onto the lower surface 92 spreads toward the outer peripheral portion of the substrate 9. A chemical liquid processing on the lower surface 92 of the substrate 9 is thereby started and heating of the substrate 9 is also started. The temperature of the heating liquid is determined as appropriate in accordance with the type of chemical liquid, the type of processing on the substrate 9, or the like, and is, e.g., about 50 to 80° C. Further, the total flow rate of the heating liquid to be supplied from the plurality of heating liquid supply nozzles 180b onto the lower surface 92 of the substrate 9 is, e.g., about 2 to 3 liters per minute.

After the substrate 9 is heated to a predetermined temperature, under the control by the control part 10, the supply of the chemical liquid heated to a temperature higher than that of the substrate 9 is started from the upper nozzle 181 toward the center portion of the upper surface 91 of the substrate 9 being rotated. The discharge of the chemical liquid toward the upper surface 91 of the substrate 9 is performed only on the center portion of the substrate 9, not on any portion other than the center portion. The chemical liquid from the upper nozzle 181 is continuously supplied onto the upper surface 91 of the substrate 9 being rotated. With the rotation of the substrate 9, the chemical liquid on the upper surface 91 spreads toward the outer peripheral portion of the substrate 9, and the entire upper surface 91 is covered with the chemical liquid.

The supply of the heating liquid from the heating liquid supply nozzles 180b continues also while the chemical liquid is supplied from the upper nozzle 181. In the enlarged sealed space 100, while the substrate 9 is heated to approximately a predetermined temperature, etching is thereby performed on the upper surface 91 of the substrate 9 by using the chemical liquid supplied from the upper nozzle 181 and etching is also performed on the lower surface 92 of the substrate 9 by using the heating liquid supplied from the heating liquid supply nozzles 180b (Step S12). The flow rate of the chemical liquid to be supplied from the upper nozzle 181 onto the upper surface 91 of the substrate 9 is, e.g., about 0.5 to 1 liter per minute. Since the lower surface of the top plate 123 is close to the upper surface 91 of the substrate 9, the etching of the substrate 9 is performed in a very narrow space between the lower surface of the top plate 123 and the upper surface 91 of the substrate 9.

In the enlarged sealed space 100, the chemical liquid scattered from the upper surface 91 of the substrate 9 being rotated is received by the cup part 161 through the annular opening 81 and led toward the liquid receiving recessed portion 165. The chemical liquid led to the liquid receiving recessed portion 165 flows into the gas-liquid separating part 193 through the first exhaust path 191 shown in FIG. 17. In the chemical liquid collecting part 195, the chemical liquid is collected from the gas-liquid separating part 193, and after removing impurities or the like from the chemical liquid through a filter or the like, the chemical liquid is reused.

After a predetermined time (e.g., 60 to 120 seconds) elapses from the start of the supply of the chemical liquid from the upper nozzle 181, the supply of the chemical liquid from the upper nozzle 181 and the supply of the heating liquid from the heating liquid supply nozzles 180b are stopped. Then, the substrate rotating mechanism 15 increases the number of rotation of the substrate 9 to be higher than the steady number of rotation for a predetermined time period (e.g., 1 to 3 seconds), to thereby remove the chemical liquid from the substrate 9.

Subsequently, when the chamber cover 122 and the cup part 161 synchronously moves down. Then, as shown in FIG. 21, the lip seal 231 positioned at the lower end of the outer edge portion of the chamber cover 122 comes into contact with an upper portion of the chamber sidewall 214, to thereby close the annular opening 81, and the chamber space 120 becomes sealed, being isolated from the side space 160. The cup part 161 is located at the escape position like in the state of FIG. 16. Hereinafter, the state of the chamber 12 and the cup part 161 shown in FIG. 21 is referred to as a “second sealed state”. In the second sealed state, the substrate 9 directly faces an inner wall of the chamber 12, and there is not any other liquid receiving part therebetween.

Also in the second sealed state, like in the first sealed state, the substrate retaining part 142 presses the substrate 9 toward the substrate supporting part 141, and it is thereby possible to strongly hold the substrate 9 being sandwiched from above and below by the substrate retaining part 142 and the substrate supporting part 141. Further, the plate holding part 222 releases holding of the top plate 123, and the top plate 123, being independent of the chamber cover 122, is rotated together with the substrate holding part 14 and the substrate 9.

After the chamber space 120 becomes sealed, the exhaust of the gas by the outer gas exhaust part 194 (see FIG. 17) is stopped and the exhaust of gas from the chamber space 120 by the inner gas exhaust part 198 is started. Then, the supply of the deionized water serving as a rinse liquid or a cleaning solution onto the substrate 9 is started by the deionized water supply part 184 (Step S13).

The deionized water from the deionized water supply part 184 is discharged from the upper nozzle 181 and the lower nozzle 182 and continuously supplied onto the respective center portions of the upper surface 91 and the lower surface 92 of the substrate 9. With the rotation of the substrate 9, the deionized water spreads toward the respective outer peripheral portions of the upper surface 91 and the lower surface 92 and is scattered outward from the outer peripheral edge of the substrate 9. The deionized water scattered from the substrate 9 is received by the inner wall of the chamber 12 (i.e., the respective inner walls of the chamber cover 122 and the chamber sidewall 214) and discarded through the second exhaust path 192, the gas-liquid separating part 197, and the liquid exhaust part 199 shown in FIG. 17 (the same applies to a drying process on the substrate 9 described later). With this operation, as well as a rinse process and a cleaning process on the upper surface 91 and the lower surface 92 of the substrate 9, cleaning of the inside of the chamber 12 is substantially performed.

After a predetermined time elapses from the start of supply of the deionized water, the supply of the deionized water from the deionized water supply part 184 is stopped. Then, under the control by the control part 10, the ejection of the inert gas (i.e., the heating gas) heated to a temperature higher than that of the substrate 9 is started from the plurality of heating gas supply nozzles 180a toward the lower surface 92 of the substrate 9. The heating gas from each heating gas supply nozzle 180a is continuously ejected toward the lower surface 92 of the substrate 9 between the central axis J1 and the outer peripheral edge of the substrate 9. The heating gas ejected onto the lower surface 92 of the substrate 9 from the heating gas supply nozzle 180a spreads toward a space below the substrate 9. The substrate 9 is thereby heated. The temperature of the heating gas is, e.g., about 160 to 200° C. Further, the total flow rate of the heating gas to be supplied from the plurality of heating gas supply nozzles 180a is, e.g., about 150 to 200 liters per minute.

Subsequently, the IPA is supplied onto the upper surface 91 of the substrate 9 from the upper nozzle 181, and the deionized water is replaced with the IPA on the upper surface 91 (Step S14). After a predetermined time elapses from the start of supply of the IPA, the supply of the IPA from the IPA supply part 185 is stopped. After that, while the ejection of the heating gas from the heating gas supply nozzles 180a continues, the number of rotation of the substrate 9 is increased to be sufficiently higher than the steady number of rotation. The IPA is thereby removed from the substrate 9, and drying of the substrate 9 is performed (Step 15). After a predetermined time elapses from the start of drying of the substrate 9, the rotation of the substrate 9 is stopped. The drying of the substrate 9 may be performed in a reduced pressure atmosphere in which the pressure of the chamber space 120 is reduced by the inner gas exhaust part 198 to be lower than the atmosphere pressure.

After that, the chamber cover 122 and the top plate 123 move up, and the chamber 12 is brought into the open state as shown in FIG. 16. In Step S15, since the top plate 123 is rotated together with the substrate supporting part 141, almost no liquid remains on the lower surface of the top plate 123 and therefore, no liquid drops from the top plate 123 onto the substrate 9 when the chamber cover 122 moves up. The substrate 9 is unloaded from the chamber 12 by the external transfer mechanism (Step S16).

As described above, in the substrate processing apparatus 1a, provided are the upper nozzle 181 for supplying the chemical liquid having a temperature higher than that of the substrate 9 onto the upper surface 91 of the substrate 9 and the heating liquid supply nozzles 180b for supplying the heating liquid having a temperature higher than that of the substrate 9 onto the lower surface 92 of the substrate 9 between the central axis J1 and the outer peripheral edge of the substrate 9. It is thereby possible to suppress or prevent a decrease in the temperature of the substrate 9 and the temperature of the chemical liquid supplied onto the upper surface 91 of the substrate 9 from the center portion of the substrate 9 toward the outer peripheral portion thereof. As a result, it is possible to improve the uniformity of the temperature of the substrate 9 and the temperature of the chemical liquid on the substrate 9, and also improve the inplane uniformity of the etching on the upper surface 91 of the substrate 9. Further, the etching of the lower surface 92 of the substrate 9 by using the heating liquid can be performed concurrently with the etching of the upper surface 91.

Thus, in the substrate processing apparatus 1a, it is possible to improve the uniformity of the temperature of the substrate 9 and the temperature of the chemical liquid on the substrate 9. For this reason, the constitution of the substrate processing apparatus 1a is especially suitable for a substrate processing apparatus in which the temperature of the chemical liquid supplied onto the upper surface 91 of the substrate 9 is relatively easy to decrease from the center portion of the substrate 9 toward the outer peripheral portion thereof, e.g., a substrate processing apparatus in which the upper nozzle 181 for discharging the chemical liquid onto the upper surface 91 of the substrate 9 is so fixed as to face the center portion of the upper surface 91. In the substrate processing apparatus in which the upper nozzle 181 is so fixed as to face the center portion of the upper surface 91 of the substrate 9, since a moving distance of the chemical liquid supplied on the upper surface 91, which travels on the substrate 9, until the chemical liquid is scattered from the outer edge is long, it is possible to efficiently use the chemical liquid supplied on the upper surface 91 for the etching process.

In the substrate processing apparatus 1a, the heating gas supply nozzles 180a for supplying the heating gas having a temperature higher than that of the substrate 9 toward the lower surface 92 of the substrate 9 between the central axis J1 and the outer peripheral edge of the substrate 9 are further provided. Since the substrate 9 can be thereby heated without supplying any liquid to the substrate 9 in drying the substrate 9, it is possible to increase the volatility of the IPA on the substrate 9. As a result, it is possible to quickly dry the substrate 9 and suppress or prevent any damage of the fine pattern on the upper surface 91 of the substrate 9 in drying the substrate 9.

In the substrate processing apparatus 1a, two or more heating liquid supply nozzles 180b among the plurality of heating liquid supply nozzles 180b are positioned on the same circumference around the central axis J1. It is thereby possible to reduce the time after each portion of the substrate 9 above the circle passes above the heating liquid supply nozzle 180b to be supplied with the heating liquid until the portion moves to above the next heating liquid supply nozzle 180b. It is further thereby possible to suppress a decrease in the temperature while each portion of the substrate 9 moves between the heating liquid supply nozzles 180b (in other words, a decrease in the temperature during rotation). As a result, it is possible to improve the uniformity of the temperature of the substrate 9 and the temperature of the chemical liquid on the substrate 9 in the circumferential direction in performing the chemical liquid processing on the substrate 9 and further improve the inplane uniformity of the etching on the substrate 9.

Further, in the substrate processing apparatus 1a, provided are the plurality of heating liquid supply nozzles 180b having different distances from the central axis J1 in the radial direction. In other words, a distance between one heating liquid supply nozzle 180b among the plurality of heating liquid supply nozzles 180b and the central axis J1 in the radial direction is different from that between another heating liquid supply nozzle 180b and the central axis J1 in the radial direction. For this reason, it is possible to much further suppress or prevent a decrease in the temperature of the chemical liquid supplied onto the upper surface 91 of the substrate 9 from the center portion of the substrate 9 toward the outer peripheral portion thereof. As a result, it is possible to improve the uniformity of the temperature of the substrate 9 and the temperature of the chemical liquid on the substrate 9 in the radial direction and further improve the inplane uniformity of the etching on the upper surface 91 of the substrate 9.

As mentioned above, the chemical liquid supplied onto the upper surface 91 of the substrate 9 from the upper nozzle 181 and the heating liquid supplied onto the lower surface 92 of the substrate 9 from the heating liquid supply nozzles 180b are the same liquid supplied from one chemical liquid supply part 183. The liquid (chemical liquid) is heated by one liquid heating part 188 before being supplied to the upper nozzle 181 and the heating liquid supply nozzles 180b. It is thereby possible to simplify the structure of the substrate processing apparatus 1a and downsize the substrate processing apparatus 1a.

In the substrate processing apparatus 1a, two or more heating gas supply nozzles 180a among the plurality of heating gas supply nozzles 180a are positioned on the same circumference around the central axis J1. It is thereby possible to reduce the time after each portion of the substrate 9 above the circle passes above the heating gas supply nozzle 180a to be supplied with the heating gas until the portion moves to above the next heating gas supply nozzle 180a. It is thereby possible to suppress a decrease in the temperature while each portion of the substrate 9 moves between the heating gas supply nozzles 180a (in other words, a decrease in the temperature during rotation). As a result, it is possible to improve the uniformity of the temperature of the substrate 9 in the circumferential direction in drying the substrate 9 and more quickly dry the substrate 9. Further, it is possible to much further suppress or prevent any damage of the fine pattern on the upper surface 91 of the substrate 9 in drying the substrate 9.

In the substrate processing apparatus 1a, provided are the plurality of heating gas supply nozzles 180a having different distances from the central axis J1 in the radial direction. In other words, a distance between one heating gas supply nozzle 180a among the plurality of heating gas supply nozzles 180a and the central axis J1 in the radial direction is different from that between another heating gas supply nozzle 180a and the central axis J1 in the radial direction. It is thereby possible to improve the uniformity of the temperature of the substrate 9 in the radial direction and more quickly dry the substrate 9. Further, it is possible to much further suppress or prevent any damage of the fine pattern on the upper surface 91 of the substrate 9 in drying the substrate 9.

As described above, the heating liquid supply nozzles 180b protrude from the facing surface 211a of the lower surface facing part 211. It is thereby possible to suppress the flow of the processing liquid such as deionized water or the like which is supplied onto the lower surface 92 of the substrate 9 from the lower nozzle 182 into the heating liquid supply nozzles 180b from the discharge ports 1805. Further, since the heating liquid supply nozzles 180b are each inclined with respect to the central axis J1, it is possible to much further suppress the flow of the processing liquid such as deionized water or the like into the heating liquid supply nozzles 180b.

The heating gas supply nozzles 180a also protrude from the facing surface 211a of the lower surface facing part 211. It is thereby possible to suppress the flow of the chemical liquid supplied onto the lower surface 92 from the heating liquid supply nozzles 180b and the flow of the deionized water supplied onto the lower surface 92 of the substrate 9 from the lower nozzle 182 into the heating gas supply nozzles 180a from the ejection ports 1802. Further, since the heating gas supply nozzles 180a are each inclined with respect to the central axis J1, it is possible to much further suppress the flow of the chemical liquid, the deionized water, or the like into the heating gas supply nozzles 180a.

As described above, the facing surface 211a of the lower surface facing part 211 is a sloped surface which gets farther away from the substrate 9 as a distance from the central axis J1 becomes larger. It is thereby possible to easily guide the processing liquid such as the chemical liquid, the deionized water, or the like which is supplied onto the lower surface 92 of the substrate 9 toward the outer side of the facing surface 211a in the radial direction. As a result, it is also possible to prevent the processing liquid from being accumulated on the facing surface 211a.

FIG. 22 is a graph showing a temperature distribution of the substrate 9 in performing the chemical liquid processing (Step S12) while supplying the heating liquid onto the lower surface 92 of the substrate 9 in the substrate processing apparatus 1a. FIG. 22 shows the temperature distribution of the substrate 9 having a radius of about 150 mm. In FIG. 22, the horizontal axis represents a distance between each measurement position and the central axis J1 in the radial direction and the vertical axis represents a temperature of the substrate 9 at the measurement position (the same applies to FIG. 23). In FIG. 22, a white square represents a temperature of the substrate 9 in performing the chemical liquid processing in the substrate processing apparatus 1a and a black circle represents a temperature of a substrate in performing the chemical liquid processing in a substrate processing apparatus of the above-described first comparative example. In the substrate processing apparatus of the first comparative example, no heating liquid supply nozzle is provided, and a chemical liquid having a temperature higher than that of the substrate is supplied onto an upper surface of the substrate from an upper nozzle and no heating liquid is supplied onto a lower surface of the substrate. As shown in FIG. 22, in the substrate processing apparatus 1a, as compared with in the substrate processing apparatus of the first comparative example, it is possible to suppress a decrease in the temperature of the substrate 9 from the center portion of the substrate 9 toward the outer peripheral portion thereof.

In the substrate processing apparatus 1a, in a case where the chemical liquid processing on the lower surface 92 of the substrate 9 is not performed in performing the chemical liquid processing on the upper surface 91 of the substrate 9, instead of supplying the heating liquid from the heating liquid supply nozzles 180b, the heating gas may be supplied onto the lower surface 92 of the substrate 9 from the heating gas supply nozzles 180a concurrently with supplying the chemical liquid from the upper nozzle 181. FIG. 23 is a graph showing a temperature distribution of the substrate 9 in performing the chemical liquid processing (Step S12) in the case where the heating gas is supplied onto the lower surface 92 of the substrate 9 instead of the heating liquid. In FIG. 23, a white triangle represents a temperature of the substrate 9 in performing the chemical liquid processing in the substrate processing apparatus 1a and a black circle represents a temperature of the substrate in performing the chemical liquid processing in the substrate processing apparatus of the above-described first comparative example. As shown in FIG. 23, also in the case where the heating gas is supplied onto the lower surface 92 of the substrate 9 in performing the chemical liquid processing, it is possible to suppress a decrease in the temperature of the substrate 9 from the center portion of the substrate 9 toward the outer peripheral portion thereof as compared with in the substrate processing apparatus of the first comparative example.

Assuming that a substrate processing apparatus in which a substrate is processed in an open processing space is considered as a comparative example (hereinafter, referred to as a “substrate processing apparatus of the second comparative example”), in the substrate processing apparatus of the second comparative example, in order to prevent diffusion of the gas containing a chemical liquid component to the outside, the gas is exhausted in a high flow rate from the processing space during the processing of the substrate by using the chemical liquid. Further, in order to prevent deposition of particles on the substrate, a downflow is formed. Therefore, an airflow from upper toward lower is formed around the substrate, and the temperature of the substrate becomes easy to decrease due to the airflow. The decrease in the temperature of the substrate becomes more remarkable at an outer edge portion of the substrate, and the uniformity of the temperature distribution of the substrate is deteriorated. As a result, the uniformity of the processing of the substrate by using the chemical liquid is deteriorated. Though it may be possible to suppress deterioration in the uniformity of the temperature distribution of the substrate by supplying the chemical liquid which is heated to a certain temperature onto the substrate in a high flow rate, the amount of chemical liquid consumed disadvantageously increases.

On the other hand, in the substrate processing apparatus 1a, the enlarged sealed space 100 which is a sealed space smaller than the processing space in the substrate processing apparatus of the second comparative example is formed by the chamber 12, the cup part 161, and the cup facing part 163 which serve as the sealed space forming part. It is thereby possible to suppress diffusion of heat from the substrate 9.

In the substrate processing apparatus 1a in which the enlarged sealed space 100 is formed, since the gas containing the chemical liquid component is not diffused outside and there is low necessity of the downflow which is formed in order to prevent deposition of particles on the substrate, it is possible to set the amount of gas flowing into the enlarged sealed space 100 and the amount of gas flowing out of the enlarged sealed space 100 low. Therefore, it is possible to further reduce the decrease in the temperature of the substrate 9. As a result, it is possible to improve the uniformity of the temperature distribution of the substrate while setting the flow rate of the heating liquid from the heating liquid supply nozzles 180b relatively low. Further, since it is not necessary to supply the chemical liquid which is heated to a certain temperature onto the upper surface 91 of the substrate 9 in a high flow rate (in other words, it is possible to reduce the amount of chemical liquid consumed), it is possible to also reduce the COO (Cost Of Ownership) of the substrate processing apparatus 1a.

In the substrate processing apparatus 1a, in performing the above-described chemical liquid processing, Step S121 shown in FIG. 12 may be executed instead of Step S12. In Step S121, under the control by the control part 10, the heated chemical liquid is supplied onto the upper surface 91 of the substrate 9 being rotated from the upper nozzle 181, and concurrently with the supply of the chemical liquid, the heating liquid is supplied onto the lower surface 92 of the substrate 9 from the heating liquid supply nozzles 180b, like in Step S12. In Step S121, concurrently with the supply of the chemical liquid from the upper nozzle 181 and the supply of the heating liquid from the heating liquid supply nozzles 180b, the heating gas is further supplied into a space below the substrate 9 from the heating gas supply nozzles 180a.

The supply of the heating gas into the space below the substrate 9 from the heating gas supply nozzles 180a is performed more gently than the ejection of the heating gas from the heating gas supply nozzles 180a in the above-described drying process on the substrate 9 (Step S15). For this reason, it is possible to prevent the heating liquid supplied onto the lower surface 92 of the substrate 9 from the heating liquid supply nozzles 180b from being flicked off the lower surface 92 by the heating gas from the heating gas supply nozzles 180a and the flow of the heating liquid running on the lower surface 92 from being disturbed by the heating gas from the heating gas supply nozzles 180a.

In Step S121, in a heating gas atmosphere where high-temperature heating gas is supplied into the space below the substrate 9, the heating liquid from the heating liquid supply nozzles 180b is supplied onto the lower surface 92 of the substrate 9 and moved on the lower surface 92 toward the outer peripheral portion. It is thereby possible to suppress a decrease in the temperature of the heating liquid during periods while the heating liquid is supplied onto the substrate 9 and moved on the substrate 9.

The above-described substrate processing apparatuses 1 and 1a allow various variations.

In the substrate processing apparatus 1 shown in FIG. 1, for example, in the lower surface facing part 211, the heating gas pipe 808 and the heating liquid pipe 806 do not necessarily need to be provided as a double tube, but may be provided separately from each other. Further, the heating liquid manifold 807 does not necessarily need to be provided.

In the substrate processing apparatus 1 shown in FIG. 1, each supply nozzle 180 does not necessarily need to be provided as a double tube in which the heating liquid supply nozzle 180b is positioned on the inner side of the heating gas supply nozzle 180a. The structure of the supply nozzle 180 may be changed in various manners only if the heating gas supply nozzle 180a and the heating liquid supply nozzle 180b share a partition wall which comes into direct contact with the heating gas and the heating liquid, to form one supply nozzle 180. As shown in FIG. 24, for example, there may be another structure in which the inside of a supply nozzle 180c having a cylindrical shape is divided into two parts by a partition wall 803. In the supply nozzle 180c, the right side of the partition wall 803 serves as the heating gas supply nozzle 180a and the left side of the partition wall 803 serves as the heating liquid supply nozzle 180b.

In the substrate processing apparatuses 1 and 1a, there may be another case where the lower nozzle 182 is connected to the liquid heating part 188 and the chemical liquid supply part 183 and the heating liquid (i.e., the chemical liquid heated to a temperature higher than that of the substrate 9) is supplied also onto the center portion of the lower surface 92 when the heating liquid is supplied onto the lower surface 92 of the substrate 9 in Step S12 or S121. In other words, the lower nozzle 182 facing the center portion of the lower surface 92 of the substrate 9 may be included in the plurality of heating liquid supply nozzles 180b.

In the substrate processing apparatuses 1 and 1a, instead of the liquid heating part 188, a first liquid heating part for heating the chemical liquid to be supplied from the chemical liquid supply part 183 to the upper nozzle 181 and a second liquid heating part for heating the chemical liquid to be supplied from the chemical liquid supply part 183 to the heating liquid supply nozzles 180b independently of the first liquid heating part may be provided. It thereby becomes possible to individually control the temperature of the chemical liquid to be supplied onto the upper surface 91 of the substrate 9 and the temperature of the heating liquid to be supplied onto the lower surface 92 of the substrate 9.

The upper nozzle 181 does not necessarily need to be so fixed as to face the center portion of the upper surface 91 of the substrate 9. The upper nozzle 181 may have, for example, a structure to supply a processing liquid (i.e., the above-described chemical liquid, deionized water, IPA, or the like) while repeating a reciprocating motion between the center portion of the substrate 9 and the outer edge portion thereof above the substrate 9, only if the upper nozzle 181 can supply the processing liquid onto at least the center portion of the upper surface 91.

The processing liquid to be supplied onto the upper surface 91 of the substrate 9 from the upper nozzle 181 and the heating liquid to be supplied onto the lower surface 92 of the substrate 9 from the heating liquid supply nozzles 180b may be different liquids. Further, the inert gas to be supplied into the chamber 12 from the upper nozzle 181 and the heating gas to be supplied from the heating gas supply nozzle 180a may be different gases. There may be a case, for example, where in drying the substrate 9, nitrogen gas is supplied from the upper nozzle 181 and dry air is supplied from the heating gas supply nozzles 180a. It is thereby possible to reduce the running cost for drying of the substrate 9.

In the substrate processing apparatus 1 shown in FIG. 1, the facing surface 211a of the lower surface facing part 211 in the chamber bottom 210 may be a surface parallel to the lower surface 92 of the substrate 9. Further, the number of supply nozzles 180 provided on the lower surface facing part 211 may be one or more than one. In other words, in the substrate processing apparatus 1, at least one supply nozzle 180 is provided. The positions of the supply nozzles 180 in the radial direction and the number of nozzles provided on the same circumference may be changed as appropriate in accordance with the temperature of the substrate 9 or the like which is required in performing the chemical liquid processing or drying.

In the substrate processing apparatus 1a shown in FIG. 16, the facing surface 211a of the lower surface facing part 211 in the chamber bottom 210 may be a surface parallel to the lower surface 92 of the substrate 9. Further, the number of heating gas supply nozzles 180a provided on the lower surface facing part 211 may be one or more than one. The number of heating liquid supply nozzles 180b may be also one or more than one. In other words, in the substrate processing apparatus 1a, at least one heating gas supply nozzle 180a and at least one heating liquid supply nozzle 180b are provided. The positions of the heating gas supply nozzles 180a and the heating liquid supply nozzles 180b in the radial direction and the number of nozzles provided on the same circumference may be changed as appropriate in accordance with the temperature of the substrate 9 or the like which is required in performing the chemical liquid processing or drying.

In the substrate processing apparatuses 1 and 1a, a pressurizing part for supplying gas into the chamber space 120 to pressurize the chamber space 120 may be provided. The chamber space 120 is pressurized in the second sealed state in which the chamber 12 is sealed and brought into a pressurized atmosphere where the pressure thereof is higher than the atmosphere pressure. Further, the inert gas supply part 186 or the heating gas supply part 187 may also serve as the pressurizing part.

The chamber opening and closing mechanism 131 does not necessarily need to move the chamber cover 122 in the vertical direction, but may move the chamber body 121 in the vertical direction with the chamber cover 122 fixed. The shape of the chamber 12 is not necessarily limited to a substantially cylindrical shape but may be any of various shapes.

The shapes and structures of the stator part 151 and the rotor part 152 in the substrate rotating mechanism 15 may be changed in various manners. The rotor part 152 does not necessarily need to rotate, being in a floating state. There may be another case where a structure such as a guide or the like for mechanically supporting the rotor part 152 is provided in the chamber 12 and the rotor part 152 rotates along the guide. The substrate rotating mechanism 15 does not necessarily need to be a hollow motor, but an axis rotation type motor may be used as the substrate rotating mechanism.

In the substrate processing apparatus 1, the enlarged sealed space 100 may be formed by bring any portion (e.g., the sidewall 611) of the cup part 161 other than the upper surface part 612 into contact with the chamber cover 122. The shape of the cup part 161 may be changed as appropriate.

In the substrate processing apparatuses 1 and 1a, the shapes of the upper nozzle 181, the lower nozzle 182, the supply nozzle 180, the heating gas supply nozzle 180a, and the heating liquid supply nozzle 180b are not limited to a protruding shape. Any portion having a discharge port for discharging the processing liquid and/or the heating liquid or an ejection port for ejecting the inert gas and/or the heating gas may be included in a concept of the nozzle in the preferred embodiments of the present invention.

In the substrate processing apparatuses 1 and 1a, various processings utilizing chemical reaction, other than the above-described etching, such as removal of an oxide film on the substrate, development using a developing solution, or the like, may be performed by using the chemical liquid supplied from the chemical liquid supply part 183.

The substrate processing apparatuses 1 and 1a may be used for processing a glass substrate used in a display device such as a liquid crystal display, a plasma display, an FED (Field Emission Display), and the like, other than the semiconductor substrate. Alternatively, the substrate processing apparatus 1 may be used for processing a substrate for optical disk, a substrate for magnetic disk, a substrate for magneto-optic disk, a substrate for photomask, a ceramic substrate, a substrate for solar battery, and the like.

The configurations of the above-described preferred embodiments and variations may be appropriately combined as long as there are no mutual inconsistencies.

While the invention has been shown and described in detail, the foregoing description is in all aspects illustrative and not restrictive. It is therefore understood that numerous modifications and variations can be devised without departing from the scope of the invention. This application claims priority benefit under 35 U.S.C. Section 119 of Japanese Patent Application No. 2013-052878 filed in the Japan Patent Office on Mar. 15, 2013 and Japanese Patent Application No. 2013-052879 filed in the Japan Patent Office on Mar. 15, 2013, the entire disclosures of which are incorporated herein by reference.

### REFERENCE SIGNS LIST

1, 1a Substrate processing apparatus
9 Substrate
10 Control part
12 Chamber
15 Substrate rotating mechanism
91 Upper surface (of Substrate)
92 Lower surface (of Substrate)
100 Enlarged sealed space
121 Chamber body
122 Chamber cover
141 Substrate supporting part
161 Cup part
163 Cup facing part
180, 180c Supply nozzle
180a Heating gas supply nozzle
180b Heating liquid supply nozzle
181 Upper nozzle
188 Liquid heating part
211 Lower surface facing part
211a Facing surface
801 Inner peripheral wall
J1 Central axis
S11 to S16, S121 Step

1. A substrate processing apparatus for processing a substrate, comprising:
a substrate supporting part for supporting an outer edge portion of a substrate in a horizontal state;
a substrate rotating mechanism for rotating said substrate supporting part together with said substrate around a central axis directed in a vertical direction;
a processing liquid supply nozzle for supplying a processing liquid having a temperature higher than that of said substrate onto an upper surface of said substrate; and
at least one supply nozzle directed to a lower surface of said substrate between said central axis and an outer peripheral edge of said substrate,
wherein each supply nozzle of said at least one supply nozzle comprises:
a heating liquid supply nozzle for supplying a heating liquid having a temperature higher than that of said substrate onto said lower surface of said substrate; and
a heating gas supply nozzle for ejecting heating gas having a temperature higher than that of said substrate toward said lower surface of said substrate, said heating gas supply nozzle sharing a partition wall which comes into direct contact with said heating liquid and said heating gas, with said heating liquid supply nozzle.

2. The substrate processing apparatus according to claim 1, wherein
said each supply nozzle is a double tube in which said heating gas supply nozzle surrounds the periphery of said heating liquid supply nozzle.

3. The substrate processing apparatus according to claim 1, wherein
said at least one supply nozzle includes a plurality of supply nozzles, and
two or more supply nozzles among said plurality of supply nozzles are positioned on the same circumference around said central axis.

4. The substrate processing apparatus according to claim 1, wherein
said at least one supply nozzle includes a plurality of supply nozzles, and
a distance between one supply nozzle among said plurality of supply nozzles and said central axis in a radial direction is different from that between another supply nozzle and said central axis in said radial direction.

5. The substrate processing apparatus according to claim 1, wherein
said processing liquid and said heating liquid are the same liquid,
said substrate processing apparatus further comprising:
a liquid heating part for heating said liquid to be supplied to said processing liquid supply nozzle and said heating liquid supply nozzle of said each supply nozzle.

6. The substrate processing apparatus according to claim 5, wherein
said heating liquid in said heating liquid supply nozzle is heated by said heating gas in said heating gas supply nozzle through said partition wall in said each supply nozzle, to have a temperature higher than that of said processing liquid.

7. The substrate processing apparatus according to claim 1, wherein
said heating liquid in said heating liquid supply nozzle is heated by said heating gas in said heating gas supply nozzle through said partition wall in said each supply nozzle.

8. The substrate processing apparatus according to claim 1, wherein
said substrate supporting part has an annular shape around said central axis,
said substrate processing apparatus further comprising:
a lower surface facing part having a facing surface which faces said lower surface of said substrate inside said substrate supporting part,
wherein said facing surface is a sloped surface which gets farther away from said substrate as a distance from said central axis becomes larger.

9. The substrate processing apparatus according to claim 1, wherein
said at least one supply nozzle is inclined with respect to said central axis.

10. The substrate processing apparatus according to claim 1, wherein
said processing liquid supply nozzle is so fixed as to face a center portion of said upper surface of said substrate.

11. The substrate processing apparatus according to claim 1, further comprising:
a sealed space forming part forming an internal space which is sealed, in which a processing is performed on said substrate with said processing liquid.

12. A substrate processing apparatus for processing a substrate, comprising:
a substrate supporting part for supporting an outer edge portion of a substrate in a horizontal state;
a substrate rotating mechanism for rotating said substrate supporting part together with said substrate around a central axis directed in a vertical direction;
a processing liquid supply nozzle for supplying a processing liquid having a temperature higher than that of said substrate onto an upper surface of said substrate;
at least one heating liquid supply nozzle for supplying a heating liquid having a temperature higher than that of said substrate onto a lower surface of said substrate between said central axis and an outer peripheral edge of said substrate; and
at least one heating gas supply nozzle for ejecting heating gas having a temperature higher than that of said substrate toward said lower surface of said substrate between said central axis and said outer peripheral edge of said substrate.

13. The substrate processing apparatus according to claim 12, wherein
said at least one heating liquid supply nozzle includes a plurality of heating liquid supply nozzles, and
two or more heating liquid supply nozzles among said plurality of heating liquid supply nozzles are positioned on the same circumference around said central axis.

14. The substrate processing apparatus according to claim 12, wherein
said at least one heating liquid supply nozzle includes a plurality of heating liquid supply nozzles, and
a distance between one heating liquid supply nozzle among said plurality of heating liquid supply nozzles and said central axis in a radial direction is different from that between another heating liquid supply nozzle and said central axis in said radial direction.

15. The substrate processing apparatus according to claim 12, wherein
said at least one heating gas supply nozzle includes a plurality of heating gas supply nozzles, and
two or more heating gas supply nozzles among said plurality of heating gas supply nozzles are positioned on the same circumference around said central axis.

16. The substrate processing apparatus according to claim 12, wherein
said at least one heating gas supply nozzle includes a plurality of heating gas supply nozzles, and
a distance between one heating gas supply nozzle among said plurality of heating gas supply nozzles and said central axis in a radial direction is different from that between another heating gas supply nozzle and said central axis in said radial direction.

17. The substrate processing apparatus according to claim 12, wherein
said processing liquid and said heating liquid are the same liquid,
said substrate processing apparatus further comprising:
a liquid heating part for heating said liquid to be supplied to said processing liquid supply nozzle and said at least one heating liquid supply nozzle.

18. The substrate processing apparatus according to claim 12, wherein
said substrate supporting part has an annular shape around said central axis,
said substrate processing apparatus further comprising:
a lower surface facing part having a facing surface which faces said lower surface of said substrate inside said substrate supporting part,
wherein said facing surface is a sloped surface which gets farther away from said substrate as a distance from said central axis becomes larger.

19. The substrate processing apparatus according to claim 12, wherein
said at least one heating gas supply nozzle is inclined with respect to said central axis.

20. The substrate processing apparatus according to claim 12, wherein
said processing liquid supply nozzle is so fixed as to face a center portion of said upper surface of said substrate.

21. The substrate processing apparatus according to claim 12, further comprising:
a sealed space forming part forming an internal space which is sealed, in which a processing is performed on said substrate with said processing liquid.

22. The substrate processing apparatus according to claim 12, further comprising:
a control part for controlling said substrate rotating mechanism, supply of said processing liquid from said processing liquid supply nozzle, supply of said heating liquid from said at least one heating liquid supply nozzle, and supply of said heating gas from said at least one heating gas supply nozzle,
wherein said processing liquid is supplied onto said upper surface of said substrate, and concurrently with the supply of said processing liquid, said heating liquid is supplied onto said lower surface of said substrate, with said substrate being rotated, and after stopping supply of said processing liquid and said heating liquid, said heating gas is ejected toward said lower surface of said substrate, with said substrate being rotated, to thereby dry said substrate, under the control by said control part.

23. The substrate processing apparatus according to claim 12, further comprising:
a control part for controlling said substrate rotating mechanism, supply of said processing liquid from said processing liquid supply nozzle, supply of said heating liquid from said at least one heating liquid supply nozzle, and supply of said heating gas from said at least one heating gas supply nozzle,
wherein said processing liquid is supplied onto said upper surface of said substrate, with said substrate being rotated, and concurrently with the supply of said processing liquid, said heating liquid is supplied onto said lower surface of said substrate and said heating gas is supplied into a space below said substrate, under the control by said control part.

24. A substrate processing method of processing a substrate, comprising:
a) supplying a processing liquid having a temperature higher than that of a substrate onto an upper surface of said substrate while rotating said substrate in a horizontal state around a central axis directed in a vertical direction;
b) supplying a heating liquid having a temperature higher than that of said substrate onto a lower surface of said substrate between said central axis and an outer peripheral edge of said substrate from at least one heating liquid supply nozzle concurrently with said operation a); and
c) ejecting heating gas having a temperature higher than that of said substrate toward said lower surface of said substrate between said central axis and said outer peripheral edge of said substrate from at least one heating gas supply nozzle while rotating said substrate after stopping supply of said processing liquid and said heating liquid, to thereby dry said substrate.

25. A substrate processing method of processing a substrate, comprising:
a) supplying a processing liquid having a temperature higher than that of a substrate onto an upper surface of said substrate while rotating said substrate in a horizontal state around a central axis directed in a vertical direction;
b) supplying a heating liquid having a temperature higher than that of said substrate onto a lower surface of said substrate between said central axis and an outer peripheral edge of said substrate from at least one heating liquid supply nozzle concurrently with said operation a); and
c) supplying heating gas having a temperature higher than that of said substrate into a space below said substrate from at least one heating gas supply nozzle concurrently with said operation b).
